(19) United States
(12) Patent Application Publication
(10) Pub. No.: US 2006/0128127 A1
(43) Pub. Date: Jun. 15, 2006

(54) Method of depositing a metal compound layer and apparatus for depositing a metal compound layer

(76) Inventors: Jung-Hun Seo, Suwon-si (KR); Young-Wook Park, Suwon-si (KR); Jin-Gi Hong, Suwon-si (KR); Kyung-Bum Koo, Youngin-si (KR); Eun-Taeck Lee, Suwon-si (KR)

Correspondence Address: HARNESS, DICKEY & PIERCE, P.L.C., P.O. BOX 8910, RESTON, VA, 20195, US

(21) Appl. No.: 11/290,648

(22) Filed: Dec. 1, 2005

(30) Foreign Application Priority Data
Jun. 10, 2005 (KR) 2005-49565
Dec. 13, 2004 (KR) 2004-104741

(51) Int. Cl. H01L 21/20

(52) U.S. Cl. 438/584

(57) ABSTRACT

In a method and an apparatus for depositing a metal compound layer, a first source gas and a second source gas may be provided onto a substrate to deposit a first metal compound layer on the substrate. The first source gas may include a metal and halogen elements, and the second source gas may include a first material capable of being reacted with the metal and a second material capable of being reacted with the halogen element. The first and the second source gases may be provided at a first flow rate ratio. A second metal compound layer may be deposited on the first metal compound layer by providing the first and the second source gases with a second flow rate ratio different from the first flow rate ratio. The apparatus may include a process chamber configured to receive a substrate, a gas supply system, and a flow rate control device.

### PRIORITY CLAIM

A claim of priority is made under 35 USC § 119 to Korean Patent Application No. 2004-104741 filed on Dec. 13, 2004 and Korean Patent Application No. 2005-49565 filed on Jun. 10, 2005, the contents of which are herein incorporated by reference in their entirety.

### BACKGROUND OF THE INVENTION

1. Field of the Invention

Example embodiments of the present invention relate to a method and an apparatus for depositing a metal compound layer. More particularly, example embodiments of the present invention relate to a method and an apparatus for depositing a titanium nitride layer on a substrate.

2. Description of the Related Art

A semiconductor memory device may be manufactured by performing on a substrate, for example, a silicon wafer a series of repeated unit processes. The unit processes may include a deposition process, an oxidation process, a photolithography process, and a planarization process. A deposition process may be performed to form a layer on a substrate. An oxidation process may be performed to form an oxide layer on a substrate or to oxidize a layer on the substrate. Additionally, a photolithography process may be performed to form a desired pattern on a substrate by etching a layer on a substrate. A planarization process may be carried out to planarize a layer formed on a substrate.

Various layers may be formed on a substrate through several deposition processes, for example, a chemical vapor deposition (CVD) process, a physical vapor deposition (PVD) process, and an atomic layer deposition (ALD) process. For example, a silicon oxide layer, which may serve as a gate insulation layer, an insulating interlayer, or a dielectric layer may be formed by a CVD process. A silicon nitride layer, which may serve as a mask, an etch stop layer, or a spacer may also be formed by the CVD process. In addition, various metal compound layers, which may be used to form metal wirings, electrodes, or plugs of a semiconductor device, may be formed by the CVD process, a PVD process, or an ALD process.

In a semiconductor device, a metal composite layer, for example, a titanium nitride layer may be generally employed to form a plug that electrically connects a unit element to electrodes of a capacitor or a metal wiring. The metal composite layer may also be used as a metal barrier layer to prevent diffusions of metal atoms. The titanium nitride layer may be typically formed by the CVD process, the PVD process, or the ALD process.

A titanium nitride layer may be formed by a reaction between titanium chloride (TiCl₄) gas and ammonia (NH₃) gas at a temperature of about 680° C. An amount of chlorine (Cl) atoms remaining in the titanium nitride layer may be reduced by increasing a process temperature to form the titanium nitride layer. However, the titanium nitride layer may have improved step coverage if the process temperature is lowered. In addition, if the process temperature is increased to lower the chlorine atoms in the titanium nitride layer, underlying structures including layers and/or patterns may be damaged by thermal stress generated during the formation of the titanium nitride layer.

Recently, as an area of a unit cell of a semiconductor device has greatly reduced, various processes have been developed to manufacture a highly integrated semiconductor device. For example, a high-k material may be used to form a gate insulation layer of a transistor or a dielectric layer of a capacitor. Additionally, a low-k material may be used to form an insulating interlayer to thereby reduce a parasite capacitance between the insulating interlayer and a metal wiring. Examples of a high-k material may include yttrium oxide (Y₂O₃), hafnium oxide (HfO₂), zirconium oxide (ZrO₂), niobium oxide (Nb₂O₅), barium titanium oxide (BaTiO₃), and strontium titanium oxide (SrTiO₃).

If a titanium nitride layer is formed on a dielectric layer including hafnium oxide or zirconium oxide by a CVD process, reaction byproducts, for example, hafnium chloride (HfCl₄) or zirconium chloride (ZrCl₄) may be generated by a reaction between the dielectric layer and a source gas, for example, titanium chloride gas. The reaction byproducts may deteriorate dielectric and/or electrical characteristics of the dielectric layer. The reaction byproducts may increase a leakage current through the dielectric layer. The reaction byproducts may augment a specific resistance of the dielectric layer, which may increase a contact resistance of the capacitor.

To improve the above-mentioned problems, an ALD process may be advantageously used to form a titanium nitride layer, which may serve as a dielectric layer or a gate insulation layer. If the titanium nitride layer is formed by the ALD process, the titanium nitride layer may have improved step coverage because the titanium nitride layer may be formed at a process temperature below about 600° C. Additionally, an amount of chlorine atoms in the titanium nitride layer may be lowered by alternately providing source gases to form the titanium nitride layer. However, if the titanium nitride layer is formed by the ALD process, a manufacturing throughput of the titanium nitride layer may be reduced, compared to that of a CVD process.

A sequential flow deposition (SFD) process may be used to solve the above-mentioned problems relating to the formation of the conventional titanium nitride layer. The SFD process may include forming a titanium nitride layer on a substrate in a reaction chamber by providing reactive gases, primarily purging the reaction chamber, removing chlorine atoms from the titanium nitride layer, and secondarily purging the reaction chamber. Although the SFD process may provide a manufacturing throughput of the titanium nitride layer higher than that of an ALD process, the SFD process may provide the manufacturing throughput of the titanium nitride layer that is still lower than that of a CVD process.

### SUMMARY

In an example embodiment of the present invention, a method of depositing a metal compound layer may include providing a first source gas including a metal and a second source gas including a material capable of reacting with the metal onto a substrate to deposit a first metal compound layer on the substrate, wherein the first and the second source gases are provided at a first flow rate ratio in which a deposition rate of the first metal compound layer by a surface reaction between the first and the second source gases is substantially higher than a deposition rate of the first metal compound layer by a mass transfer between the first and the second source gases, and providing the first and the second source gases at a second flow rate ratio different then the first flow rate ratio to deposit a second metal compound layer on the first metal compound layer, and wherein the first and the second source gases simultaneously remove undesired materials from the first and the second metal compound layers.

In another example embodiment of the present invention, a method of depositing a metal compound layer may include providing a first source gas including a metal and a second source gas including a material capable of reacting with the metal onto a substrate to deposit a first metal compound layer on the substrate, wherein the first and the second source gases are provided at a first flow rate ratio in which a deposition rate of the first metal compound layer by a surface reaction between the first and the second source gases is substantially higher than a deposition rate of the first metal compound layer by a mass transfer between the first and the second source gases, providing the first and the second source gases with a second flow rate ratio different then the first flow rate ratio to deposit a second metal compound layer on the first metal compound layer, providing the first and the second source gases with a third flow rate ratio different then the first flow rate ratio to deposit a third metal compound layer on the second metal compound layer to cause a surface reaction between the first and the second source gases, and providing the first and the second source gases with a fourth flow rate ratio different then the third flow rate ratio to deposit a fourth metal compound layer on the third metal compound layer.

In an example embodiment of the present invention, an apparatus to deposit a metal compound layer may include a process chamber configured to receive a substrate, a gas supply system configured to provide a first source gas and a second source gas onto the substrate, wherein the first source gas includes a metal and the second source gas includes a material capable of reacting with the metal, and a flow rate control device configured to adjust flow rates of the first and the second source gases to deposit a first metal compound layer on the substrate, wherein the first and the second source gases are provided at a first flow rate ratio, and also configured to adjust the flow rates of the first and the second source gases to deposit a second metal compound layer on the first metal compound layer and simultaneously to remove undesired materials from the first and the second metal compound layers, wherein the first and the second source gases are provided at a second flow rate ratio different from the first flow rate ratio.

### BRIEF DESCRIPTION OF THE DRAWINGS

The present invention will become more apparent by describing in detailed example embodiments thereof with reference to the accompanying drawings, in which:

FIG. 1 is a cross-sectional view illustrating an apparatus configured to deposit a metal compound layer in accordance with an example embodiment of the present invention;

FIG. 2 is an enlarged cross-sectional view illustrating a first gas supply unit of the apparatus illustrated in FIG. 1;

FIG. 3 is a flow chart illustrating a method of depositing a metal compound layer using the apparatus illustrated in FIG. 1 in accordance with an example embodiment of the present invention;

FIG. 4 is a timing diagram illustrating feeding times of source gases in the method illustrated in FIG. 3;

FIG. 5 is a graph illustrating deposition rates of metal compound layers relative to process temperatures and flow rates of TiCl₄ gas in accordance with example embodiments of the present invention;

FIG. 6 is a graph illustrating deposition rates of metal compound layers relative to process pressures and flow rates of TiCl₄ gas at process temperatures of about 500° C. in accordance with example embodiments of the present invention;

FIG. 7 is a graph illustrating deposition rates of metal compound layers relative to process pressures and flow rates of TiCl₄ gas at process temperatures of about 700° C. in accordance with example embodiments of the present invention;

FIGS. 8A, 8B and 8C are electron microscopic pictures illustrating titanium nitride layers formed at temperatures of about 700° C. and pressures of about 5 Torr by varying flow rate ratios between source gases in accordance with example embodiments of the present invention;

FIGS. 9A, 9B and 9C are electron microscopic pictures illustrating titanium nitride layers formed at temperatures of about 500° C. and pressures of about 2 Torr by varying flow rate ratios between source gases in accordance with example embodiments of the present invention;

FIGS. 10A and 10B are timing diagrams illustrating feeding times of first source gases in the method illustrated in FIG. 3;

FIG. 11 is a cross-sectional view illustrating an apparatus for depositing a metal compound layer in accordance with another example embodiment of the present invention;

FIG. 12 is a flow chart illustrating a method of depositing a metal compound layer using the apparatus illustrated in FIG. 11 in accordance with an example embodiment of the present invention;

FIG. 13 is a timing diagram illustrating feeding times of source gases in the method illustrated in FIG. 12;

FIG. 14 is a timing diagram illustrating a feeding time of a first source gas provided on a substrate in the method illustrated in FIG. 12;

FIG. 15 is a graph showing a deposition rate of a titanium nitride layer relative to a number of cycles in a sequential flow deposition (SFD) process;

FIG. 16 is a graph showing a deposition rate of a titanium nitride layer relative to a number of cycles in a TiCl₄ pulsed deposition (TPD) process;

FIG. 17 is a graph showing unit per equipment hour (UPEH) relative to specific resistances of titanium layers formed using SFD and TPD processes;

FIG. 18 is a cross-sectional view illustrating an apparatus to deposit a metal compound layer in accordance with another example embodiment of the present invention;

FIG. 19 is a flow chart illustrating a method of depositing a metal compound layer on a substrate using the apparatus illustrated in FIG. 18 in accordance with an example embodiment of the present invention;

FIG. 20 is a timing diagram illustrating feeding times of source gases used in the method illustrated in FIG. 19;

FIG. 21 is a cross-sectional view illustrating an apparatus for depositing a metal compound layer in accordance with an example embodiment of the present invention;

FIG. 22 is a flow chart illustrating a method of depositing a metal compound layer on a substrate using the apparatus illustrated FIG. 21 in accordance with an example embodiment of the present invention;

FIG. 23 is a timing diagram illustrating feeding times of source gases used in the method illustrated in FIG. 22;

FIG. 24 is a cross-sectional view illustrating an apparatus for depositing a metal compound layer in accordance with an example embodiment of the present invention;

FIG. 25 is a flow chart illustrating a method of depositing a metal compound layer on a substrate using the apparatus illustrated FIG. 24 in accordance with an example embodiment of the present invention;

FIG. 26 is a timing diagram illustrating feeding times of source gases used in the method illustrated in FIG. 25;

FIG. 27 is a cross-sectional view illustrating an apparatus for depositing a metal compound layer in accordance with another example embodiment of the present invention;

FIG. 28 is a flow chart illustrating a method of depositing a metal compound layer on a substrate using the apparatus illustrated in FIG. 27 in accordance with an example embodiment of the present invention;

FIG. 29 is a timing diagram illustrating feeding times of source gases used in the method of FIG. 28; and

FIG. 30 is a cross-sectional view illustrating a semiconductor device manufactured in accordance with example embodiments of the present invention.

### DESCRIPTION OF EXAMPLE EMBODIMENTS

The present invention will be described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided as working examples. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, for example, “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, for example, those defined in commonly used dictionaries, should be interpreted as having a meaning that is consistent with their meaning in the context of the relevant art and will not be interpreted in an idealized or overly formal sense unless expressly so defined herein.

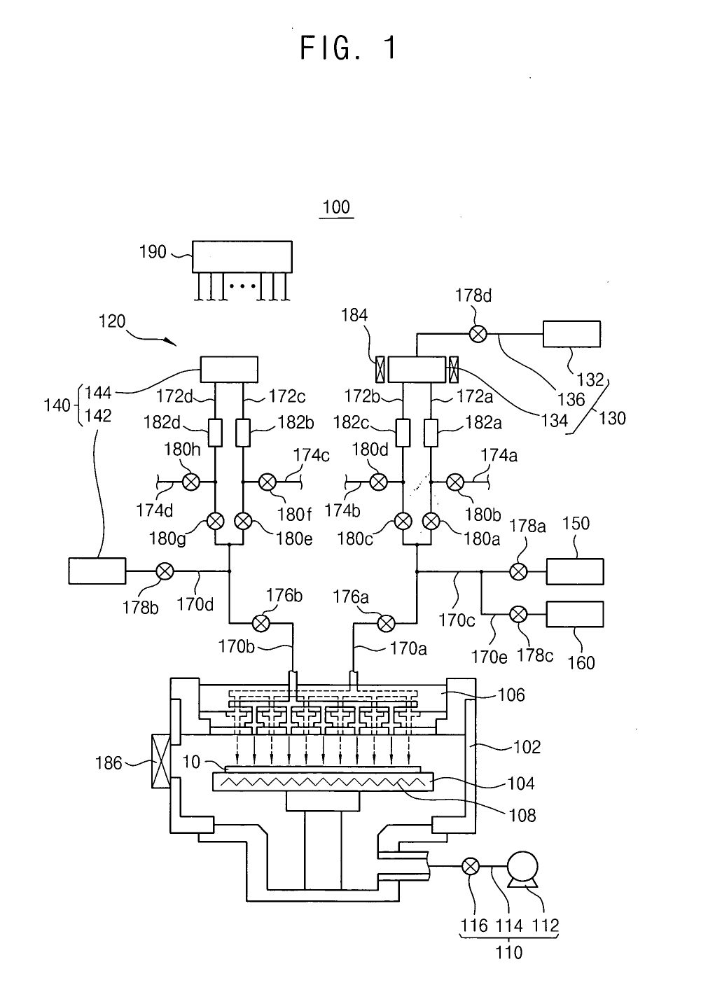

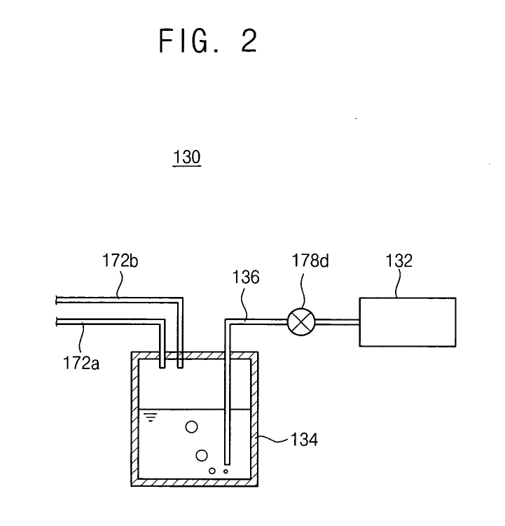

FIG. 1 is a cross-sectional view illustrating an apparatus for depositing a metal compound layer on a substrate in accordance with an example embodiment of the present invention. FIG. 2 is an enlarged cross-sectional view illustrating a first gas supply unit of the apparatus in FIG. 1.

Referring to FIGS. 1 and 2, an apparatus 100 may be configured to deposit a metal compound layer, and may be used in a deposition process to form a metal composite layer (not shown) on a substrate 10 for example, a silicon wafer or a silicon-on-insulator (SOI) substrate. For example, the apparatus 100 may be used to form a metal compound layer for example, a titanium nitride layer on the substrate 10. A metal compound layer may mean a single metal compound layer, and a metal composite layer may mean a composite metal compound layer of a least two metal compound layers.

The apparatus 100 may include a process chamber 102, a stage 104, and a gas supply system 120.

The process chamber 102 may provide a sealed space in which a deposition process of forming a metal composite layer may be carried out. The stage 104 may be disposed in the process chamber 102 to support a substrate 10 in the deposition process. The process chamber 102 may be connected to a vacuum system 110 to exhaust reaction byproducts, residual gases, purging gases and/or cleaning gases.

The gas supply system 120 may provide source gases onto the substrate 10 loaded in the process chamber 102 to form a metal composite layer on the substrate 10. The gas supply system 120 may additionally provide a purging gas into the process chamber 102 in order to purge an interior of the process chamber 102 prior to and/or after the formation of the metal composite layer.

A showerhead 106 may be disposed at an upper portion of the process chamber 102 to uniformly spray the source gases and the purging gas into the process chamber 102. The showerhead 106 may be connected to the gas supply system 120. In an example embodiment of the present invention, the purging gas may serve as a pressure control gas to adjust/control a pressure of the interior of the process chamber 102.

The gas supply system 120 may provide a first source gas and a second source gas into the process chamber 102 to thereby form the metal composite layer on the substrate 10. The first source gas may include metal and halogen elements. The second source gas may include a first material which may react with the metal of the first source gas. Additionally, the second source gas may include a second material which may react with the halogen element of the first source gas. If a titanium nitride layer is formed on the substrate 10, the first source gas and the second source gas may include a titanium chloride (TiCl₄) gas and an ammonia (NH₃) gas, respectively.

The gas supply system 120 may include a first gas supply unit 130, a second gas supply unit 140, and a third gas supply unit 150. The first gas supply unit 130 may provide the first source gas (e.g., the TiCl₄ gas) and a first carrier gas onto the substrate 10 loaded in the process chamber 102. The second gas supply unit 140 may provide the second source gas (e.g., the NH₃ gas) and a second carrier gas onto the substrate 10. The third gas supply unit 150 may provide the purging gas into the process chamber 102. The gas supply system 120 may be connected to the showerhead 106 through a plurality of connection lines (details below).

As shown in FIG. 2, the first gas supply unit 130 may include a first reservoir 132, a sealed container 134, and an immersed line 136. The first reservoir 132 may store the first carrier gas therein. The sealed container 134 may receive a first liquid source (e.g., liquid phase TiCl₄) to produce the first source gas. The immersed line 136 may extend from the first reservoir 132 to the sealed container 134. A first end of the immersed line 136 may be coupled to the first reservoir 132, and a second end of the immersed line 136 may be immersed into the first liquid source stored in the sealed container 134. The first source gas may be obtained from the first liquid source by bubbling the first liquid service provided through the immersed line 136.

In an example embodiment of the present invention, the first gas supply unit 130 may include a vaporizer. The vaporizer may directly heat the first liquid source (e.g., the liquid phase TiCl₄) to thereby produce the first source gas (e.g., the TiCl₄ gas). Alternatively, the vaporizer may take the first liquid source and convert it into a mist phase, and the vaporizer may generate the first source gas by heating the mist-phased liquid source.

The second gas supply unit 140 may include a second reservoir 142 and a second source gas tank 144. The second reservoir 142 may store the second carrier gas therein. The second source gas tank 144 may provide the second source gas (e.g., the NH₃ gas) onto the substrate 10 loaded in the process chamber 102. The third gas supply unit 150 may include a third reservoir (not shown) to provide the purging gas into the process chamber 102.

The showerhead 106 connected to the gas supply system 120 may be disposed at an upper portion of the process chamber 102 in order to provide the first and the second source gases onto the substrate 10.

The showerhead 106 may include a plurality of first nozzles and a plurality of second nozzles. The first nozzles may uniformly provide the first source gas onto the substrate 10. The second nozzles may uniformly spray the second gas onto the substrate 10. The first source gas should not be mixed with the second source gas in the showerhead 106. The first and the second source gases should be supplied onto the substrate 10 independently. If the first gas source includes the TiCl₄ gas and the second source gas contains the NH₃ gas, a titanium nitride layer may be formed on the substrate 10 through a reaction between the TiCl₄ gas and the NH₃ gas.

The showerhead 106 and the sealed container 134 of the first gas supply unit 130 may be connected to each other through a first connection line 170a, a first divided line 172a, and a second divided line 172b. The first and the second divided lines 172a and 172b may be branched from the first connection line 170a. The showerhead 106 and the second source gas tank 144 of the second gas supply unit 140 may be connected to each other through a second connection line 170b, a third divided line 172c, and a fourth divided line 172d. The third and the fourth divided lines 172c and 172d may be branched from the second connection line 170b. The third gas supply unit 150 may be connected to the first connection line 170a through a third connection line 170c. The second reservoir 142 of the second gas supply unit 140 may be connected to the second connection line 170b through a fourth connection line 170d.

The gas supply system 120 may further include a fourth gas supply unit 160 connected to the third connection line 170c through a fifth connection line 170e. The fourth gas supply unit 160 may provide a cleaning gas into the process chamber 102 to clean the interior of the process chamber 102.

In an example embodiment of the present invention, the purging gas may be provided into the showerhead 106 through the third connection line 170c and the first connection line 170a, as shown in FIG. 1. In another example embodiment of the present invention, the third connection line 170c may be connected to the second connection line 170b in order to introduce the purging gas into the showerhead 106.

Meanwhile, a first bypass line 174a, a second bypass line 174b, a third bypass line 174c, and a fourth bypass line 174d may be connected to the first divided line 172a, the second divided line 172b, the third divided line 172c, and the fourth divided line 172d, respectively.

A first gate valve 176a and a second gate valve 176b may be installed in the first connection line 170a and the second connection line 170b, respectively. A first flow control valve 178a and a second flow control valve 178b may be disposed in the third connection line 170c and the fourth connection line 170d, respectively. Additionally, a third flow control valve 178c and a fourth flow control valve 178d may be installed in the fifth connection line 170e and the immersed line 136, respectively.

A first interlocking valve 180a, a second interlocking valve 180b, a third interlocking valve 180c, and a fourth interlocking valve 180d may be installed in the first divided line 172a, the first bypass line 174a, the second divided line 172b, and the second bypass line 174d, respectively. In addition, a fifth interlocking valve 180e, a sixth interlocking valve 180f, a seventh interlocking valve 180g, and an eighth interlocking valve 180h may be disposed in the third divided line 172c, the third bypass line 174c, the fourth divided line 172d, and the fourth bypass line 174d, respectively.

A first mass flow controller 182a may be installed in the first divided line 172a to adjust a flow rate of the first source gas to a first flow. A second mass flow controller 182b may be installed in the third divided line 172c to adjust a flow rate of the second source gas to a second flow rate previously set. Additionally, a third mass flow controller 182c may be disposed in the second divided line 172b to adjust a flow rate of the first source gas to a third flow rate. A fourth mass flow controller 182d may be disposed in the fourth divided line 172d to adjust a flow rate of the second source gas to a fourth flow rate.

In an example embodiment of the present invention, the first and the third flow rates adjusted by the first and the third mass flow controllers 182a and 182c may indicate flow rates of the mixed first source gas and the first carrier gas. In the mixed gases passing through the first and the third mass flow controllers 182a and 182c, a flow rate ratio between the first source gas and the first carrier gas may be about 1.0:1.0.

The first to the fourth bypass lines 174a, 174b, 174c, and 174d may be provided to change flows of the first and the second gases into laminar flows thereof. For example, before forming a metal composite layer on a substrate 10, the first to the fourth bypass lines 174a, 174b, 174c, and 174d may be opened to convert the flows of the first and the second source gases into the laminar flows in the first to the fourth divided lines 172a, 172b, 172c, and 172d, respectively.

While the first source gas and the second source gas may be respectively provided onto the substrate 10 at the first flow rate and the second flow rate so as to deposit a first metal compound layer on the substrate 10, the first and the fifth interlocking valves 180a and 180e may be opened, whereas the second and the sixth interlocking valves 180b and 180f may be closed. Simultaneously, to bypass the first and the second source gases at the third and the fourth flow rates, the third and the seventh interlocking valves 180c and 180g may be closed, whereas the fourth and the eighth interlocking valves 180d and 180h may be opened.

On the contrary, while the first and the second source gases may be respectively introduced into the process chamber 102 at the third and the fourth flow rates in order to deposit a second metal compound layer on the first metal compound layer, the third and the seventh interlocking valves 180c and 180g may be opened, whereas the fourth and the eighth interlocking 180d and 180h may be closed. At the same time, to respectively bypass the first and the second source gases with the first and the second flow rates, the first and the fifth interlocking valves 180a and 180e may be closed but the second and the sixth interlocking valves 180b and 180f may be opened. As a result, the second metal compound layer may be continuously deposited on the first metal compound layer, and undesired materials for example, chlorine may be removed from the first and the second metal compound layers. Chlorine, which may be contained in the first and the second metal compound layers, may be removed by reacting it with the second source gas provided at the fourth flow rate. For example, chlorine may react with the second source gas to thereby generate hydrogen chloride (HCl), which may be easily removed from the first and the second metal compound layers.

A valve control unit 190 may control operations of the first to the eighth interlocking valves 180a, 180b, 180c, 180d, 180e, 180f, 180g, and 180h. The valve control unit 190 may further control operations of the first and the second gate valves 176a and 176b, and operations of the first to the fourth flow control valves 178a, 178b, 178c, and 178d.

The first carrier gas, the second carrier gas, and the purging gas may include inert gases for example, an argon (Ar) gas or a nitrogen (N₂) gas, respectively. In an example embodiment of the present invention, the first reservoir 132, the second reservoir 142, and the third reservoir may store the first source gas, the second source gas, and the purging gas, respectively. In another example embodiment of the present invention, the first source gas, the second source gas, and the purging gas may be provided from a single reservoir of the gas supply system 120 (not shown).

A first heater (not shown) may be disposed in the immersed line 136 to heat the first carrier gas provided from the first reservoir 132. The first heater may improve an evaporation efficiency of the first source gas (e.g., the TiCl₄ gas) from the first liquid source (e.g., the liquid phase TiCl₄). The first heater may supply heat to the first carrier gas so that the first carrier gas may reach a temperature substantially higher than the boiling point of the first liquid source. The first heater may heat the first carrier gas to a temperature in a range of about 100° C. to about 180° C. For example, the temperature of the first carrier gas may be about 150° C.

Heating jackets (not shown) may be respectively installed in the first connection line 170a, the first divided line 172a, and the second divided line 172b to prevent the first source gas from condensing in the respective connection lines.

A second heater 184 may be coupled to the sealed container 134 to heat the sealed container 134, thereby improving the evaporation efficiency of the first source gas from the first liquid source. The second heater 184 may include a resistance coil, which may enclose the sealed container 134.

A stage heater 108 may be further provided in the stage 104 to heat the substrate 10 to a process temperature. The stage heater 108 may also include a resistance coil. Alternatively, the stage heater 108 may include a plurality of lamps (not shown). For example, the stage heater 108 may include a plurality of halogen lamps, which may include a lamp housing and a lamp assembly. The lamp housing may contain the halogen lamps and irradiate rays generated by the halogen lamps onto the stage 104. The lamp assembly may include a transparent window disposed between the stage 104 and the halogen lamps.

A gate door 186 may be provided at a sidewall of the process chamber 102. The substrate 10 may be loaded and unloaded into the process chamber 102 through the gate door 186.

Reaction byproducts generated during the formation of the metal composite layer and residual gases may be removed from the process chamber 102 by the vacuum system 110 coupled to the process chamber 102. The vacuum system 110 may include a vacuum pump 112, a vacuum line 114, and an isolation valve 116.

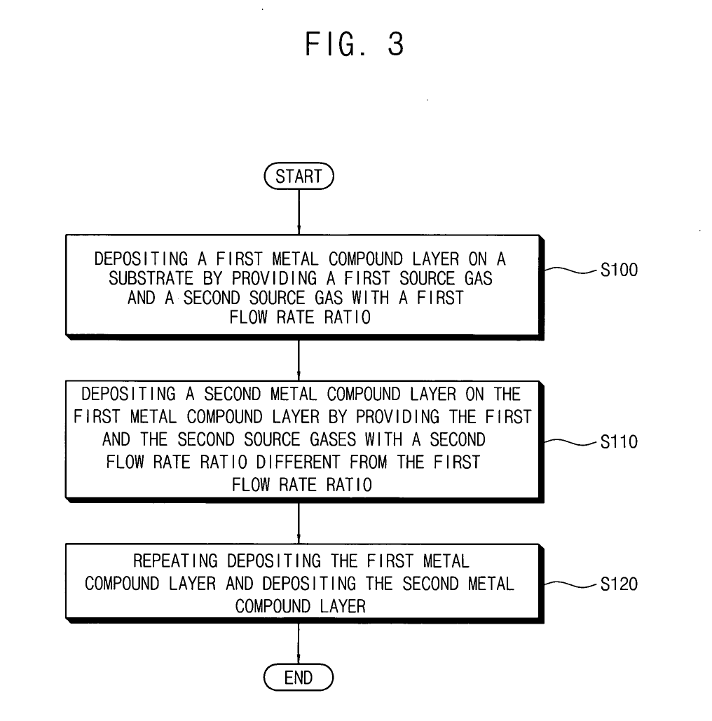

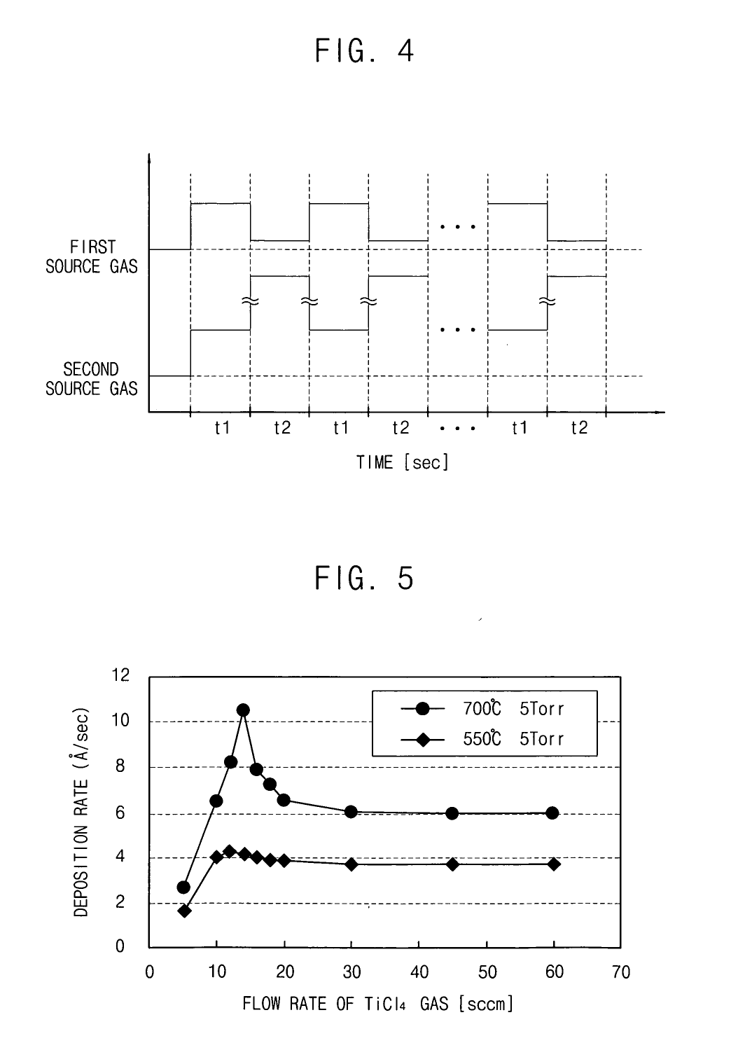

FIG. 3 is a flow chart illustrating a method of depositing a metal compound layer onto a substrate using the apparatus illustrated in FIG. 1 in accordance with an example embodiment of the present invention. FIG. 4 is a timing diagram illustrating feeding times of source gases in the method illustrated in FIG. 4.

Referring to FIGS. 1 to 4, in S100, a first metal compound layer may be deposited on a substrate 10 by providing a first source gas and a second source gas onto the substrate 10. The first source gas may include a metal and halogen elements. The second source gas may include a first material capable of reacting with the metal in the first source gas, and may include a second material capable of being reacting with the halogen element in the first source gas. For example, the first source gas may include a TiCl₄ gas, and the second source gas may include an NH₃ gas. The substrate 10 may be loaded into a process chamber 102. The first and the second source gases may be provided onto the substrate 10 to deposit the first metal compound layer on the substrate 10.

In the formation of the first metal compound layer, the first and the second mass flow controllers 182a and 182b may adjust flow rates of the first and the second source gases a first flow rate ratio. The first flow rate ratio may be in a range of about 1.0:0.5 to about 1.0:10. For example, the first flow rate ratio may be about 1.0:1.0. In other words, the first flow rate ratio may be in a range of about 0.1:1.0 to about 2.0:1.0. For example, a first flow rate of the first source gas may be about 30 sccm, and a second flow rate of the second source gas may be about 30 sccm.

When the flow rate ratio of the first flow rate relative to the second flow rate is below about 0.1, the first metal compound layer may not be properly deposited on the substrate 10. When the flow rate ratio is above about 2.0, an efficiency of the first source gas may be disadvantageously lowered even though the first metal compound layer may be continuously deposited on the substrate 10.

In S110, the second metal compound layer may be deposited on the first metal compound layer by providing the first source gas and the second source gas onto the substrate 10. At the same time, undesired materials may be removed from the first and the second metal compound layers. The first and the second source gases may be provided at a second flow rate ratio substantially different from the first flow rate ratio. In particular, the first source gas may be provided at a third flow rate substantially lower than the first flow rate, and the second source gas may be provided at a fourth flow rate substantially higher than the second flow rate. A third mass flow controller 182c and a fourth mass flow controller 182d may adjust the third flow rate of the first source gas and the fourth flow rate of the second source gas, respectively. The second flow rate ratio between the third flow rate of the first source gas and the fourth flow rate of the second source gas may be in a range of about 1.0:100 to about 1.0:1,000 to sufficiently remove the undesired materials from the first and the second metal compound layers. In other words, the second flow rate ratio between the third flow rate and the fourth flow rate may be in a range of about 0.001:1.0 to about 0.01:1.0. Additionally, a third flow rate ratio between the second flow rate and the fourth flow rate of the second gas may be in a range of about 1.0:10 to about 1.0:100. That is, the third flow rate ratio between the second and the fourth flow rates of the second gas may be in a range of about 0.01:1.0 to about 0.1:1.0. For example, in the formation of the second metal compound layer, the third flow rate of the first source gas is about 2 sccm, and the fourth flow rate of the second source gas is about 1,000 sccm.

In an example embodiment of the present invention, the second metal compound layer may be formed using the first source gas provided at the third flow rate, the second source gas provided at the fourth flow rate, and a residual first source gas which may be present in the process chamber 102. The residual first source gas may remain in the process chamber 102 after the formation of the first metal compound layer. Chlorine, which may be contained in the first and the second metal compound layers, may be removed by the second source gas provided at a relatively high flow rate as described above.

In S120, the metal composite layer (e.g., the first and the second metal compound layers) having a desired thickness may be formed on the substrate 10 by repeating the processes of S100 and S110. That is, the first process of depositing the first metal compound layer and the second process of depositing the second metal compound layer are performed in series so that the metal composite layer having the desired thickness may be formed on the substrate 10.

As shown in FIG. 4, the first process of depositing the first metal compound layer may be executed for a first period of time t1, and the second process of depositing the second metal compound layer may be executed for a second period of time t2. The first and the second processes may be respectively executed for about several seconds to about several tens of seconds. For example, the first and the second metal compound layers may be deposited for about 6 seconds, respectively.

Since chlorine may be sufficiently removed from the first and the second metal compound layers, the first and the second processes may be executed at relatively low temperatures. Accordingly, the metal composite layer may have improved step coverage. In an example embodiment of the present invention, the metal composite layer may be formed at a temperature of about 400° C. to about 600° C. and a pressure of about 0.1 Torr to about 2.5 Torr.

### Deposition Rates of Titanium Nitride Layers Relative to Process Temperatures and Flow Rates of Source Gases

To evaluate deposition rates of metal compound layers in accordance with process temperatures and flow rates of source gases, the deposition rates of a titanium nitride layer on a substrate at a temperature of about 550° C. and a temperature of about 700° C. by varying the flow rates of the source gases were measured.

FIG. 5 is a graph illustrating deposition rates of metal compound layers relative to process temperatures and flow rates of TiCl₄ gas in accordance with example embodiments of the present invention.

A first deposition rate of a first titanium nitride layer was measured by varying a flow rate of a TiCl₄ gas; a substrate was loaded in a process chamber at a first temperature of about 550° C.; and an NH₃ gas was provided at a flow rate of about 60 sccm. Additionally, a second deposition rate of a second titanium nitride layer was measured by varying a flow rate of the TiCl₄ gas; a substrate was loaded in a process chamber at a second temperature of about 700° C.; and the NH₃ gas was provided at a flow rate of about 60 sccm. In both experiments, the process chamber was at a pressure of about 5 Torr.

The measured results are illustrated in FIG. 5. Referring to FIG. 5, the second deposition rate of the second titanium nitride layer has a saturation value when the flow rate ratio of the TiCl₄ gas relative to the NH₃ gas was above about 0.5:1.0. In addition, the second deposition rate of the second titanium nitride layer has a peak value when the flow rate ratio of the TiCl₄ gas relative to the NH₃ gas was below about 0.5:1.0. The first deposition rate of the first titanium nitride layer was substantially constant when the flow rate ratio of the TiCl₄ gas relative to the NH₃ gas was above about 0.17:1.0.

The second deposition rate of the second titanium nitride layer has a substantially constant value of about 6.1 Å/sec when the flow rate of the TiCl₄ gas was above about 30 sccm at a process temperature of about 700° C. When the flow rate of the TiCl₄ gas was above about 14 sccm, the second deposition rate of the second titanium nitride layer was about 10.6 Å/sec. On the contrary, the first deposition rate of the first titanium nitride layer has a substantially constant value of about 3.8 Å/sec when the flow rate of the TiCl₄ gas was above about 30 sccm at a process temperature of about 550° C. When the flow rate of the TiCl₄ gas was below about 30 sccm, the first deposition rate of the first titanium nitride layer did not substantially changed.

As described above, the titanium nitride layer may be undesirably deposited on the substrate at the second temperature of about 700° C. when the flow rate ratio of the TiCl₄ gas relative to the NH₃ gas was below about 0.5:1.0. When the flow rate ratio of the TiCl₄ gas relative to the NH₃ gas was above about 0.5:1.0, the titanium nitride layer may be desirably formed on the substrate due to a surface reaction between the source gases for example, TiCl₄ gas and NH₃ gas. However, when the flow rate ratio of the TiCl₄ gas relative to the NH₃ gas was below about 0.5:1.0, the formation of the titanium nitride layer may mainly depended on a mass transfer between the TiCl₄ gas and the NH₃ gas rather than the surface reaction between the TiCl₄ gas and the NH₃ gas, thereby the deposited titanium nitride layer may have poor step coverage. Mass transfer means a type of phenomenon in which titanium nitride may be irregularly deposited on the substrate after the first and the second source gases provided into the process chamber react with each other over the substrate. Surface reaction means another type phenomenon where a continuous titanium nitride layer having uniform thickness may be formed on the substrate after the first and the second source gases react with each other adjacent to a surface portion of the substrate.

If the formation of the titanium nitride layer mainly depends on a mass transfer rather than a surface reaction, the titanium nitride layer may have poor step coverage. However, the titanium nitride layer may have greatly improved step coverage if the formation of the titanium nitride layer mainly depends on the surface reaction rather than the mass transfer.

As illustrated in FIG. 5, a process margin of the flow rate ratio between the TiCl₄ gas and the NH₃ gas may be more sufficiently ensured if the titanium nitride is formed at a first temperature of about 550° C. The deposition rate of the titanium nitride layer may be very uniform if the flow rate ratio of the TiCl₄ gas relative to the NH₃ gas is above about 0.5:1.0. The deposition rate of the titanium nitride layer may somewhat increase if the flow rate ratio of the TiCl₄ gas relative to the NH₃ gas is in a range of about 0.17:1.0 to about 0.5:1.0 because the mass transfer may occur at the relatively low flow rate ratio of the TiCl₄ gas with respect to the NH₃ gas. Since a difference between the saturation value and the peak value of the deposition rate is small, e.g., about 0.9 Å/sec, the process margin of the flow rate ratio between the TiCl₄ gas and the NH₃ gas at the first temperature of about 550° C. may be substantially greater than that of the flow rate ratio between the TiCl₄ gas and the NH₃ gas at a second temperature of about 700° C. Thus, the formation of the titanium nitride layer may mainly depend on the surface reaction between the first and the second source gases rather than the mass transfer between the source gases when the flow rate ratio between the first and the second source gases is in a range of about 0.17:1.0 to about 0.5:1.0. Additionally, if the titanium nitride layer is formed in accordance with the surface reaction between the source gases, the titanium nitride layer may have greatly improved step coverage.

As described above, the titanium nitride layer may have greatly enhanced step coverage and also the process margin of the flow rate ratio between the TiCl₄ gas and the NH₃ gas may increase when the titanium nitride layer is formed at a relatively low temperature. Further, the underlying structures including layers and/or patterns may have greatly reduced thermal stress in the formation of the titanium nitride layer because the titanium nitride layer is formed at a relatively low temperature.

### Deposition Rates of Titanium Nitride Layers Relative to Process Pressures and Flow Rates of Source Gases

To evaluate deposition rates of titanium nitride layers in accordance with process pressures and flow rates of source gases, the deposition rates of the titanium nitride layers were measured at process pressures of 2 Torr and about 3 Torr during the formations of the titanium nitride layers on a substrate by varying the flow rates of the source gases.

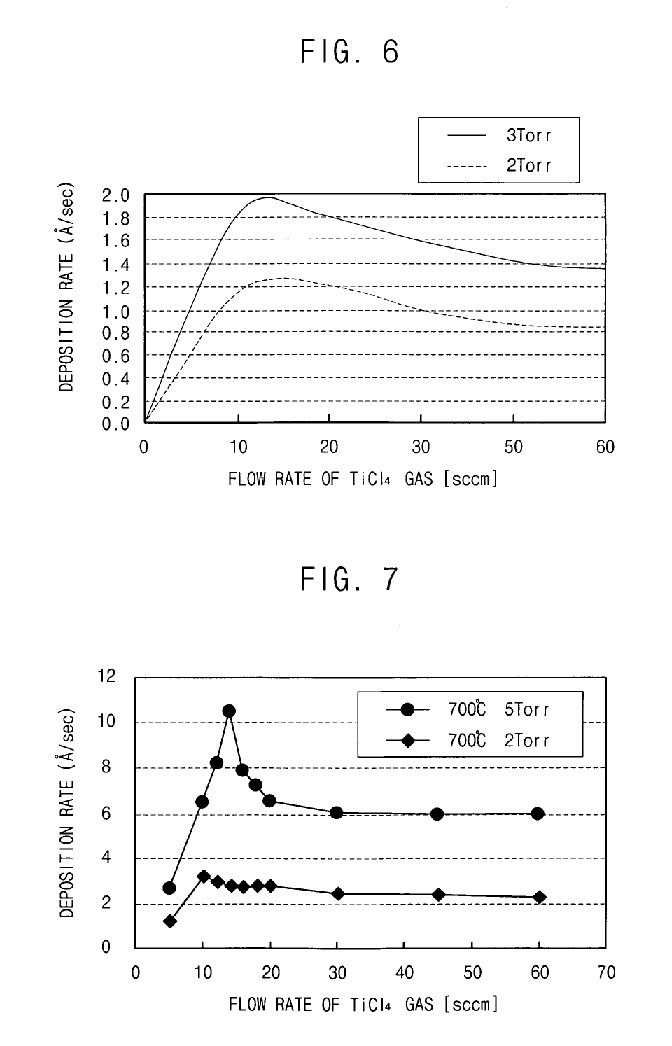

FIG. 6 is a graph illustrating deposition rates of titanium nitride layers relative to process pressures and flow rates of TiCl₄ gas at process temperatures of about 500° C. in accordance with example embodiments of the present invention.

In example embodiments of the present invention, a third deposition rate of a third titanium nitride layer was measured at a first process pressure of about 2 Torr by providing an NH₃ gas at a flow rate of about 60 sccm and by varying a flow rate of a TiCl₄ gas. A fourth deposition rate of a fourth titanium nitride layer was measured at a second process pressure of about 3 Torr by providing the NH₃ gas at a flow rate of about 60 sccm and by varying a flow rate of the TiCl₄ gas. The measured results are illustrated in FIG. 6. The third and the fourth titanium nitride layers were formed at process temperatures of about 500° C.

FIG. 7 is a graph illustrating deposition rates of titanium nitride layers relative to process pressures and flow rates of TiCl₄ gas at process temperatures of about 700° C. in accordance with example embodiments of the present invention.

In example embodiments of the present invention, a fifth deposition rate of a fifth titanium nitride layer was measured at a third process pressure of about 2 Torr by providing an NH₃ gas with a flow rate of about 60 sccm and by varying a flow rate of a TiCl₄ gas. A sixth deposition rate of a sixth titanium nitride layer was measured at a fourth process pressure of about 5 Torr by providing the NH₃ gas with a flow rate of about 60 sccm and by varying a flow rate of the TiCl₄ gas. The measured results are illustrated in FIG. 7. The fifth and the sixth titanium nitride layers were formed at process temperatures of about 700° C.

As shown in FIG. 6, the third and the fourth deposition rates of the third and the fourth titanium nitride layers may be saturated under the first pressure of about 2 Torr and the second pressure of about 3 Torr, if a flow rate ratio of the TiCl₄ gas relative to the NH₃ gas is about 1.0:1.0. However, the third deposition rate of the third titanium nitride layer formed at the first pressure of about 2 Torr was substantially higher than the fourth deposition rate of the fourth titanium nitride layer formed at the second pressure of about 3 Torr. Thus, the titanium nitride layer may have improved step coverage when the process pressure was relatively low.

Referring to FIG. 7, variations of the deposition rates of the titanium nitride layers relative to the process pressures may be similar to those of the deposition rates of the titanium nitride layers relative to the process temperatures. If the process chamber was at the third pressure of about 2 Torr, the fifth titanium nitride layer may be deposited in relatively wide flow rate ratios between the TiCl₄ gas and the NH₃ gas. The fifth deposition rate of the fifth titanium nitride layer may be similar to that of the first titanium nitride layer formed at the temperature of about 550° C. and the pressure of about 5 Torr as shown in FIG. 5. Hence, the titanium nitride layer may have enhanced step coverage by controlling at least one of the process temperature and the process pressure.

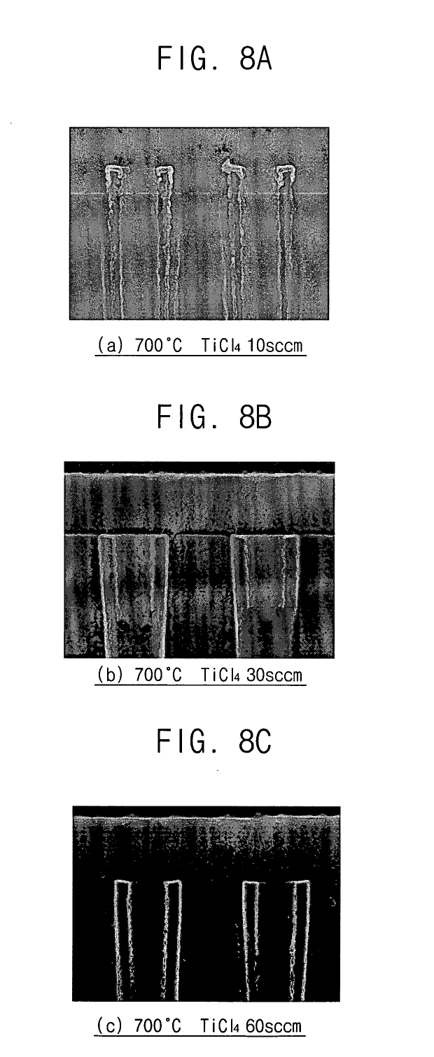

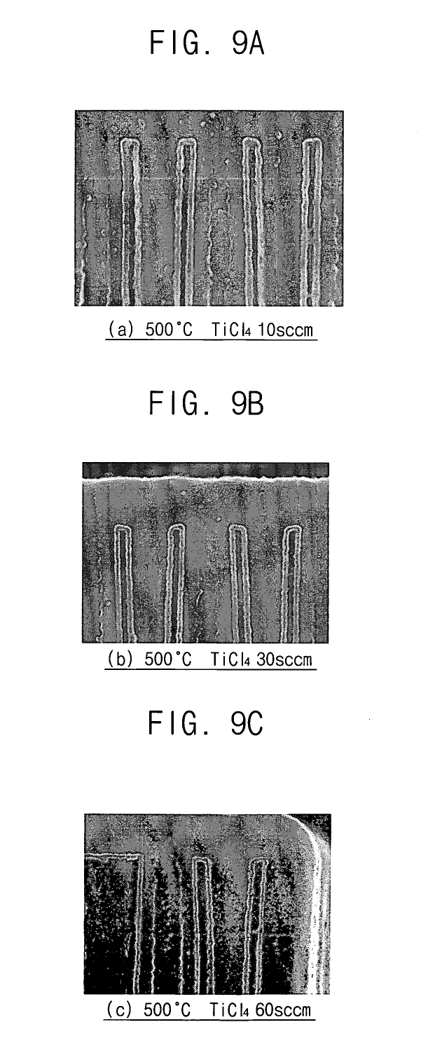

FIGS. 8A, 8B, and 8C are electron microscopic pictures illustrating titanium nitride layers formed at temperatures of about 700° C. and pressures of about 5 Torr by varying flow rate ratios between source gases in accordance with example embodiments of the present invention. FIGS. 9A, 9B, and 9C are electron microscopic pictures illustrating titanium nitride layers formed at temperatures of about 500° C. and pressures of about 2 Torr by varying flow rate ratios between source gases in accordance with example embodiments of the present invention.

Referring to FIGS. 8A, 8B, and 8C, a titanium nitride layer may be formed on a capacitor, for example a cylindrical lower electrode, at a temperature of about 700° C. and a pressure of about 5 Torr by providing an NH₃ gas at a flow rate of about 60 sccm and by providing a TiCl₄ gas with a flow rates of about 10 sccm (see FIG. 8A), about 30 sccm (see FIG. 8B), and about 60 sccm (see FIG. 8C), respectively. When the TiCl₄ gas was provided at the flow rate of about 10 sccm, the titanium nitride layer may be very irregularly formed on the lower electrode because the deposition rate of the titanium nitride layer may mainly depend on a mass transfer between the TiCl₄ gas and the NH₃ gas as shown in FIG. 8A. When the TiCl₄ gas was provided at the flow rate of about 30 sccm, the titanium nitride layer may be somewhat irregularly formed on the lower electrode, although the titanium nitride layer was more continuously formed on the lower electrode of the capacitor as shown in FIG. 8B. However, the titanium nitride layer may be very uniformly formed on the lower electrode when the TiCl₄ gas was provided at the flow rate of about 60 sccm, the flow rate which was substantially identical to that of the NH₃ gas.

Referring to FIGS. 9A, 9B, and 9C, the titanium nitride layers may be formed on a capacitor, for example a cylindrical lower electrode, at a temperature of about 500° C. and a pressure of about 2 Torr by providing an NH₃ gas with a flow rate of about 60 sccm and by providing a TiCl₄ gas with flow rates of about 10 sccm (see FIG. 9A), about 30 sccm (see FIG. 9B), and about 60 sccm (see FIG. 9C), respectively. As shown in FIGS. 9A to 9C, all of the titanium nitride layers may be very uniformly formed on the cylindrical lower electrode so that each of the titanium nitride layers may have enhanced step coverage if the titanium nitride layers were formed at relatively low temperatures.

As described above, a metal composite layer may be advantageously formed by depositing a metal compound layer for example, a titanium nitride layer at a relatively low temperature and a relatively low pressure. Therefore, the metal composite layer may have excellent step coverage and thermal stress applied to the underlying structure may be greatly reduced. In example embodiments of the present invention, a leakage current from the titanium nitride layer may be greatly reduced if the titanium nitride layer was formed on a lower electrode of a capacitor or a metal barrier layer of a gate structure in a transistor.

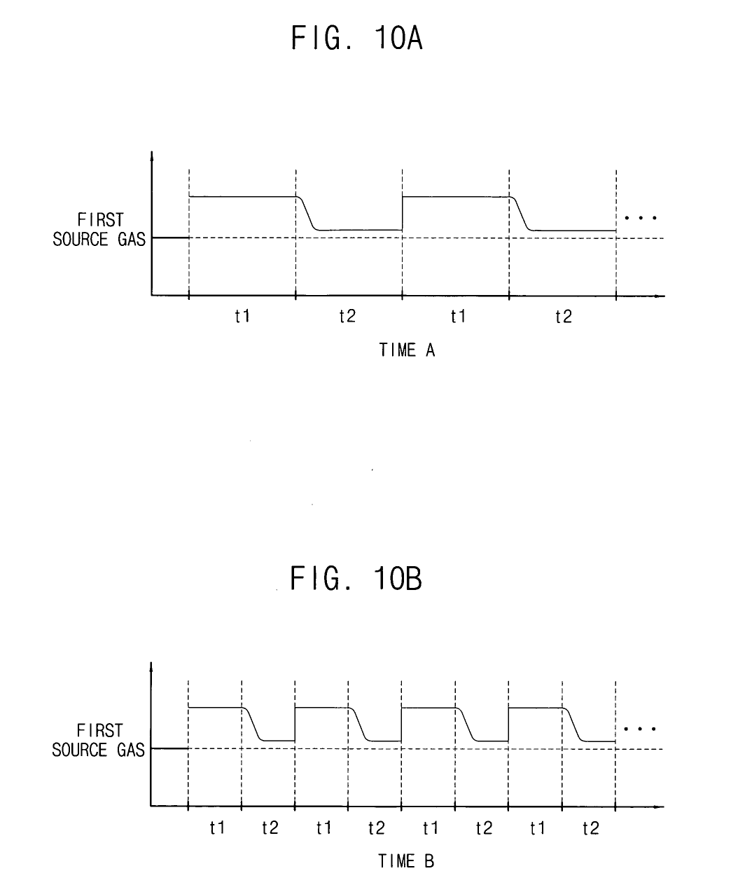

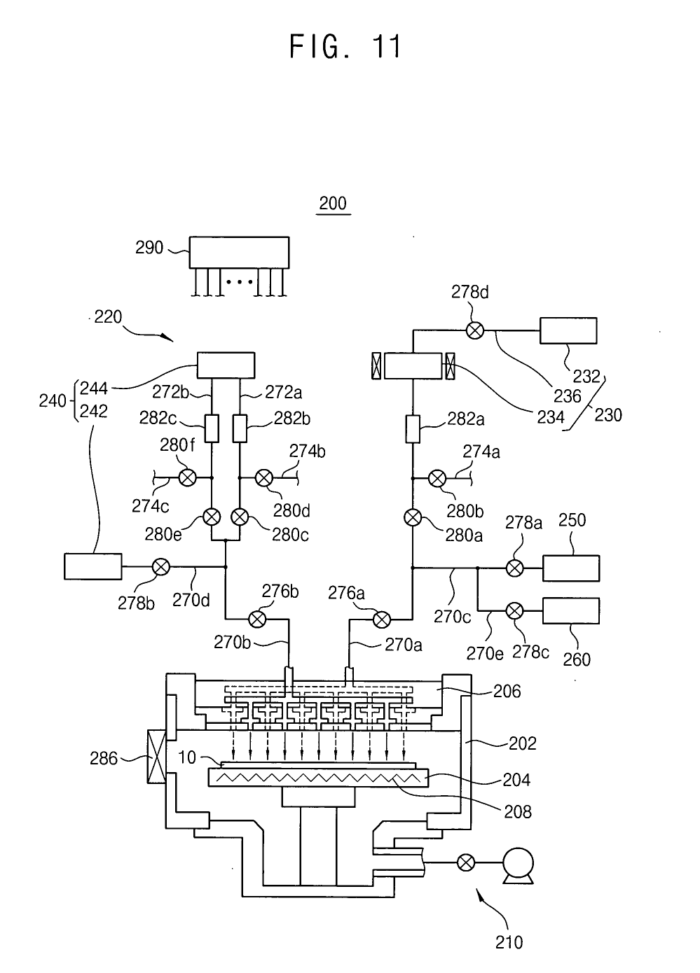

FIGS. 10A and 10B are timing diagrams illustrating feeding times of a first source gas in a method according to example embodiments of the present invention. FIG. 10A shows a first feeding time A for a first source gas when processes for depositing metal compound layers were repeated twice. FIG. 10B shows a second feeding time B for the first source gas when processes for depositing metal compound layers were repeated four times.

Referring to FIGS. 3, 10A and 10B, an amount of the first source gas provided for a first feeding time A may be substantially greater than an amount of the first source gas provided for the second feeding time B because some of the first source gas provided in S100 may remain in the process chamber 102 while S110 process is carried out. In other words, the amount of the first source gas may be augmented according as the number of cycles including the first and the second processes may be increased for a desired process time. Accordingly, a deposition rate of the metal compound layer may be properly controlled by adjusting the number of cycles of the first and the second processes, thereby improving a manufacturing throughput by an apparatus 100 of FIG. 1. Further, chlorine, which may be included in the metal compound layers, may be effectively removed from the metal compound layers depending on the augmented number of cycles so that the metal compound layers may have greatly reduced specific resistance.

FIG. 11 is a cross-sectional view illustrating an apparatus for depositing a metal compound layer in accordance with another example embodiment of the present invention.

Referring to FIG. 11, an apparatus 200 to deposit a metal compound layer may be used during a deposition process to form a metal composite layer for example, a titanium nitride layer on a substrate 10.

The apparatus 200 may include a process chamber 202, a stage 204, a vacuum system 210, and a gas supply system 220.

The stage 204 may be disposed in the process chamber 202 to support the substrate 10 during the deposition process. The vacuum system 210 may create a pressure in an interior of the process chamber 202.

The gas supply system 220 may provide a first source gas and a second source gas onto the substrate 10 to form a metal composite layer on the substrate 10. The gas supply system 220 may be connected to a showerhead 206 disposed at an upper portion of the process chamber 202.

The showerhead 206 may include a plurality of first nozzles and a plurality of second nozzles to spray the first and the second source gases onto the substrate 10.

The gas supply system 220 may provide the first and the second source gases onto the substrate 10 to form the metal composite layer on the substrate 10. If a titanium nitride layer is formed on the substrate 10, the first source gas may include titanium and chlorine, and the second source gas may include nitrogen and hydrogen. For example, the first source gas and the second source gases may include a TiCl₄ gas and an NH₃ gas, respectively.

The first source gas and the second source gas may be introduced into the process chamber 202 together with a first carrier gas and a second carrier gas, respectively.

The gas supply system 220 may provide a purging gas into the process chamber 202 to purge the interior of the process chamber 202. The purging gas may additionally serve as a pressure control gas to control/adjust the pressure of an interior of the process chamber 202. In an example embodiment of the present invention, the gas supply system 220 may further provide a cleaning gas into the process chamber 202 to clean the interior of the process chamber 202.

The gas supply system 220 may include a first gas supply unit 230, a second gas supply unit 240, a third gas supply unit 250, and a fourth gas supply unit 260. The gas supply system 220 may be connected to the showerhead 206 through a plurality of connection lines. The first gas supply unit 230 may provide the first source gas (e.g., the TiCl₄ gas) and the first carrier gas onto the substrate 10 loaded into the process chamber 202. The second gas supply unit 240 may provide the second source gas (e.g., the NH₃ gas) and the second carrier gas onto the substrate 10. The third gas supply unit 250 may provide the purging gas into the process chamber 202, and the fourth gas supply unit 260 may introduce the cleaning gas into the process chamber 202.

The first gas supply unit 230 may include a first reservoir 232, a sealed container 234, and an immersed line 236. The first reservoir 232 may store the first carrier gas therein. The sealed container 234 may receive a first liquid source (e.g., liquid phase TiCl₄) to generate the first source gas. The immersed line 236 may extend from the first reservoir 232 to the sealed container 234. The first source gas may be obtained by bubbling the first carrier gas provided through the immersed line 236. In an example embodiment of the present invention, the first gas supply unit 230 may include a vaporizer.

The second gas supply unit 240 may include a second reservoir 242 and a second source gas tank 244. The second reservoir 242 may store the second carrier gas therein, and the second source gas tank 244 may provide the second source gas (e.g., the NH₃ gas) into the process chamber 202.

A first connection line 270a may connect the showerhead 206 to the sealed container 234 of the first gas supply unit 230. The showerhead 206 may be connected to the second source gas tank 244 of the second gas supply unit 240 through a second connection line 270b. In addition, the showerhead 206 may be connected to the second source gas tank 244 through a first divided line 272a and a second divided line 272b, which may be branched from the second connection line 270b.

A third connection line 270c may connect the third gas supply line 250 to the first connection line 270a. The second reservoir 242 of the second gas supply unit 240 may be connected to the second connection line 270b through a fourth connection line 270d.

The fourth gas supply unit 260 may be connected to the third connection line 270c through a fifth connection line 270e to provide the cleaning gas into the process chamber 202.

A first bypass line 274a, a second bypass line 274b, and a third bypass line 274c may be coupled to the first connection line 270a, the first divided line 272a, and the second divided line 272b, respectively.

A first gate valve 276a and a second gate valve 276b may be disposed in the first connection line 270a and the second connection line 270b, respectively. A first flow control valve 278a, a second flow control valve 278b, a third flow control valve 278c, and a fourth flow control valve 278d may be installed in the third connection line 270c, the fourth connection valve 270d, the fifth connection valve 270e, and the immersed line 236, respectively.

A first interlocking valve 280a, a second interlocking valve 280b, a third interlocking valve 280c, a fourth interlocking valve 280d, a fifth interlocking valve 280e, and a sixth interlocking valve 280f may be disposed in the first connection line 270a, the first bypass line 274a, the first divided line 272a, the second bypass line 274b, the second divided line 272b, and the third bypass line 274c, respectively.

A first mass flow controller 282a may be disposed in the first connection line 270a to adjust a flow rate of the first source gas to a first flow rate. A second mass flow controller 282b may be installed in the first divided line 272a to adjust a flow rate of the second source gas to a second flow rate. A third mass flow controller 282c may be installed in the second divided line 272b to adjust the flow rate of the second source gas to a third flow rate.

While the first source gas and the second source gas are provided onto the substrate 10 at the first flow rate and the second flow rate in order to deposit a first metal compound layer on the substrate 10, the first and the third interlocking valves 280a and 280c may be opened, whereas the second and the fourth interlocking valves 280b and 280d may be closed. Also, to bypass the second source gas with the third flow rate, the fifth interlocking valve 280e may be closed but the sixth interlocking valve 280f may be opened.

After depositing the first metal compound layer on the substrate 10, the fifth interlocking valve 280e may be opened and the sixth interlocking valve 280f may be closed while the second source gas may be provided on the first metal compound layer with the third flow rate. Simultaneously, the first and the third interlocking valves 280a and 280c may be closed, whereas the second and the fourth interlocking valves 280b and 280d may be opened in order to bypass the first and the second source gases with the first and the second flow rates, respectively. Accordingly, a second metal compound layer may be continuously deposited on the first metal compound layer, and undesired materials for example, chlorine may be removed from the first and the second metal compound layers in accordance with a reaction between the second source gas provided at the third flow rate and a residual first source gas in the process chamber 202 after the formation of the first metal compound layer.

A valve control unit 290 may control operations of the first to the sixth interlocking valves 280a, 280b, 280c, 280d, 280e, and 280f. The valve control unit 290 may further adjust operations of the first and the second gate valves 276a, and 276b, and performances of the first to the fourth flow control valves 278a, 278b, 278c, and 278d.

The stage 204 may include a heater 208 to heat the substrate 10 to a desired process temperature. A gate door 286 may be disposed at a sidewall of the process chamber 202 to load and unload the substrate 10 into the process chamber 202. Reaction byproducts generated during the formation of a metal composite layer and residual gases may be removed from the process chamber 202 by the vacuum system 210 connected to the process chamber 202.

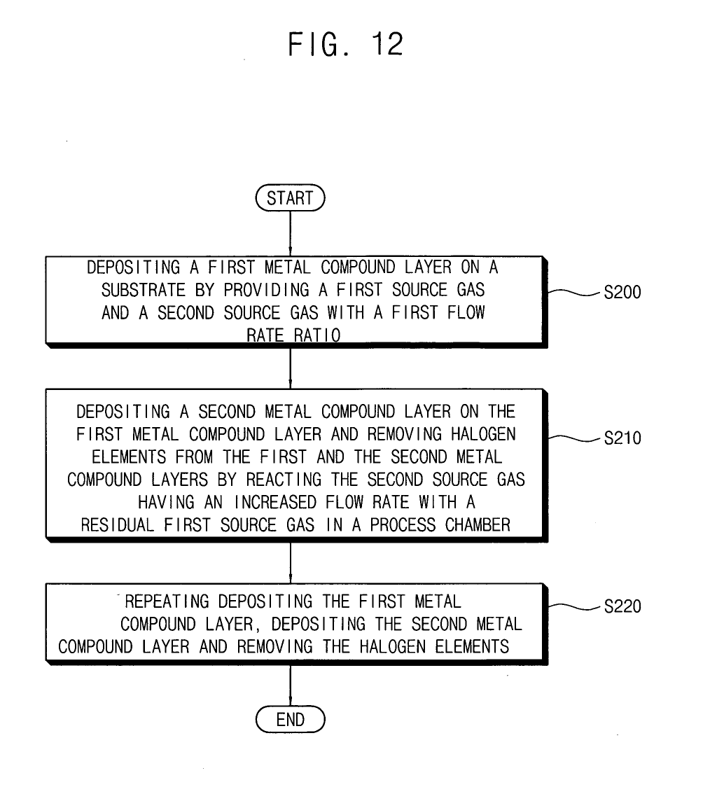

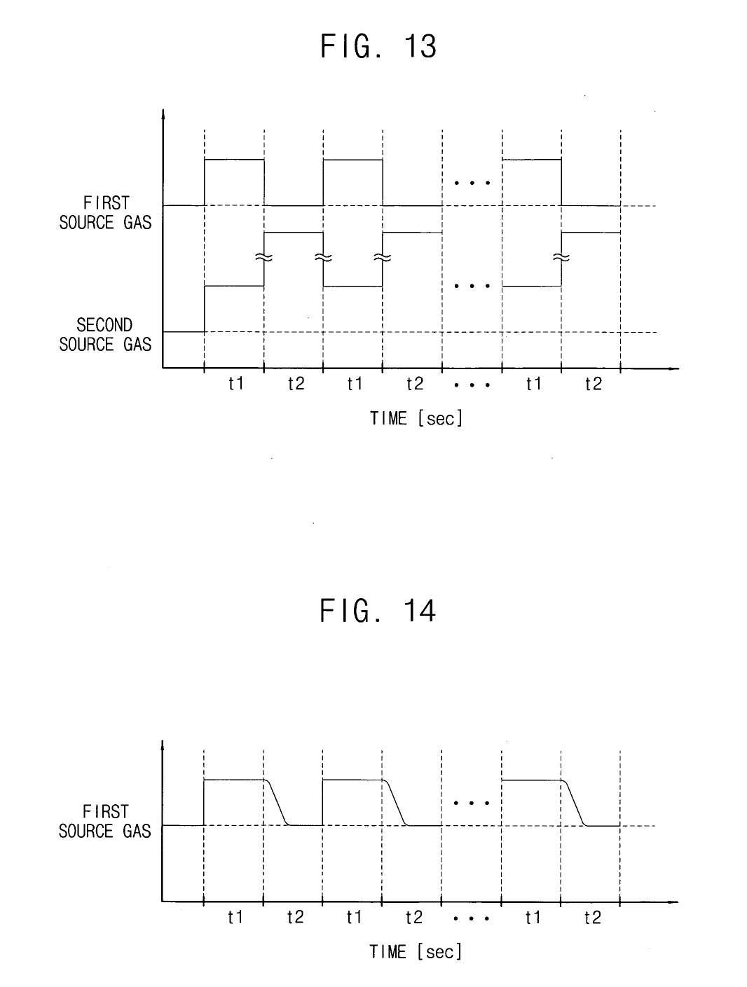

FIG. 12 is a flow chart illustrating a method of depositing a metal compound layer on a substrate using the apparatus illustrated in FIG. 11 in accordance with an example embodiment of the present invention. FIG. 13 is a timing diagram illustrating feeding times of source gases in the method illustrated in FIG. 12, and FIG. 14 is a timing diagram illustrating a feeding time of a first source gas provided on a substrate in the method illustrated in FIG. 12.

Referring to FIGS. 11 to 14, in S200, a first metal compound layer may be deposited on a substrate 10 by providing a first source gas and a second source gas onto the substrate 10. The first source gas may include a metal and halogen elements. The second source gas may include a first material capable of reacting with the metal in the first source gas, and may include a second material capable of reacting with the halogen element in the first source gas. The first and the second source gases are provided onto the substrate 10 loaded in the process chamber 202 at a first flow rate ratio. For example, the first source gas may include a TiCl₄ gas, and the second source gas may include an NH₃ gas.

During the formation of the first metal compound layer, a first mass flow controller 282a may adjust a first flow rate of the first source gas, and a second mass flow controller 282b may adjust a second flow rate of the second source gas. In an example embodiment of the present invention, the first flow rate ratio between the first flow rate of the first source gas (e.g., the TiCl₄ gas) and the second flow rate of the second source gas (e.g., the NH₃ gas) may be in a range of about 1.0:0.5 to about 1.0:10. The first flow rate ratio may be about 1.0:1.0 to deposit the first metal compound layer on the substrate 10 by a surface reaction between the first and the second source gases.

In S210, after stopping a supply of the first source gas, the second source gas may be introduced with an increased flow rate into the process chamber 202 so that a second metal compound layer may be deposited on the first metal compound layer by a reaction between the second source gas provided at the increased flow rate and the residual first source gas in the process chamber 202. The second source gas may be provided onto the substrate 10 at a third flow rate. While the second metal compound layer may be continuously deposited on the first metal compound layer, halogen elements (e.g., chlorine) may be removed from the first and the second metal compound layers.

A third mass flow controller 282c may adjust the third flow rate of the second source gas to form the second metal compound layer and to remove the halogen elements. The third flow rate of the second source gas may be substantially higher than the second flow rate. In an example embodiment of the present invention, a second flow rate ratio between the second flow rate and the third flow rate may be in a range of about 1.0:10 to about 1.0:100.

In S220, a metal composite layer having a desired thickness may be formed on the substrate 10 by repeating processes S200 and S210. Namely, a first process of depositing the first metal compound layer and a second process of depositing the second metal compound layer may be performed in series so that the metal composite layer having a desired thickness may be formed on the substrate 10.

As shown in FIG. 13, the first source gas may be provided onto the substrate 10 with the first flow rate for a first period of time t1, and the second process may be provided onto the first metal compound layer with the second flow rate for the first period of time t1 in S200. In S210, the supply of the first source gas may be ceased, whereas the second source gas may be provided onto the substrate 10 for a second period of time t2 with the increased third flow rate. Since the first source gas may remain in the process chamber 202 after S200 to form the first metal compound layer, the residual first source gas may react with the second source gas to thereby continuously deposit the second metal compound layer on the first metal compound layer although the first source gas may be not provided in S210. For example, the first and the second source gases (e.g., the TiCl₄ gas and the NH₃ gas) may be introduced into the process chamber 202 at flow rates of about 60 sccm, respectively, in S200. In S210, the second gas may be provided onto the substrate 10 at a flow rate of, for example, about 1,000 sccm.

A first interlocking valve 280a may be closed to stop the supply of the first source gas in S210. However, as shown in FIG. 14, the residual first source gas in the process chamber 202 may be continuously provided onto the substrate 10 even though the supply of the first source gas may have ceased by the first interlocking valve 280a. Thus, the flow rate of the residual first source gas in S210 may be substantially lower than the first flow rate of the first source gas in S200. In the formation of the second metal compound layer, the supply of the residual first source gas may be gradually reduced by reacting the residual first source gas with the second source gas to completely consume the residual first source gas. If the second period of time t2 of the second source gas is substantially shorter than a time to exhaust the first source gas from the process chamber 202, the flow rate of the first source gas may gradually decreased in S210. If the second period of time t2 of the second source gas is substantially long, the flow rate of the first source gas may be gradually reduced, and the residual first source gas may be completely consumed in S210.

In S200 and S210, the substrate 10 may have a process temperature of about 400 to about 600° C., and the process chamber 202 may have a process pressure of about 0.1 to about 2.5 Torr. For example, the substrate 10 may have a process temperature of about 500° C., and the process chamber 202 may have a process pressure of about 2.0 Torr.

In example embodiments of the present invention, the above-described method of depositing a titanium layer may be referred to as a TiCl₄ pulsed deposition (TPD) process. If a titanium nitride layer is formed on a substrate by the TPD process in accordance with example embodiments of the present invention, the titanium nitride layer may have greatly improved electrical characteristics higher than those of the conventional titanium nitride layer formed by the SFD process.

### Evaluation of Characteristics of Titanium Nitride Layers Formed by an SFD Process and a TPD Process

A sixth titanium nitride may be formed on a substrate by the above-mentioned SFD process. A TiCl₄ gas and an NH₃ gas may be provided onto a substrate with flow rates of about 60 sccm, respectively, for about 6 seconds to form the titanium nitride layer on the substrate, a process chamber may be purged for about 3 seconds using nitrogen gas. The NH₃ gas may be provided onto the sixth titanium nitride layer at a flow rate of about 1,000 sccm for about 6 seconds to remove chlorine, which may be in the titanium nitride layer. The nitrogen gas may be introduced into the process chamber for about 3 seconds to purge the process chamber. These processes of forming the titanium nitride layer may be repeated about twenty-four times. That is, the number of cycles including the above-described processes may be about twenty-four. In the SFD process, the substrate may have a temperature of about 500° C., and the process chamber may have a pressure of about 3 Torr.

A seventh titanium nitride layer may be formed on a substrate by a TPD process of example embodiments of the present invention. A TiCl₄ gas and an NH₃ gas may be provided onto a substrate at flow rates of about 60 sccm, respectively, for about 6 seconds, thereby to form a first titanium nitride layer on the substrate loaded in a process chamber. After stopping a supply of the TiCl₄ gas, the NH₃ gas may be provided onto the first titanium nitride layer at a flow rate of about 1,000 sccm for about 6 seconds, thereby continuously forming a second titanium nitride layer on the first titanium nitride layer and simultaneously removing chlorine, which may be contained in the first and the second titanium nitride layers. The cycle including the above-described processes to form the first and the second titanium nitride layers may be repeated about twenty-four times. Namely, the number of the cycles to form the first and the second nitride layers may be about twenty-four. In the TPD process, the substrate may have a temperature of about 500° C., and the process chamber may have a pressure of about 2 Torr.

The sixth titanium nitride layer formed by the SFD process may have a specific resistance of about 329 μΩcm, whereas the seventh titanium nitride layer formed by the TPD process may have a specific resistance of about 283 μΩcm. The sixth titanium nitride layer may have a thickness uniformity of about 12.1%, whereas the seventh titanium nitride layer may have a thickness uniformity of about 6.0%. As a result, the titanium nitride layer formed by the TPD process may have a lower specific resistance and improved thickness uniformity than the sixth titanium nitride layer formed by the SFD process. In addition, a process time to form the seventh titanium nitride layer using the TDP process may be considerably shorter than that of the sixth titanium nitride layer using the SFD process, thereby greatly improving a manufacturing throughput of forming the titanium nitride layer using the TPD process.

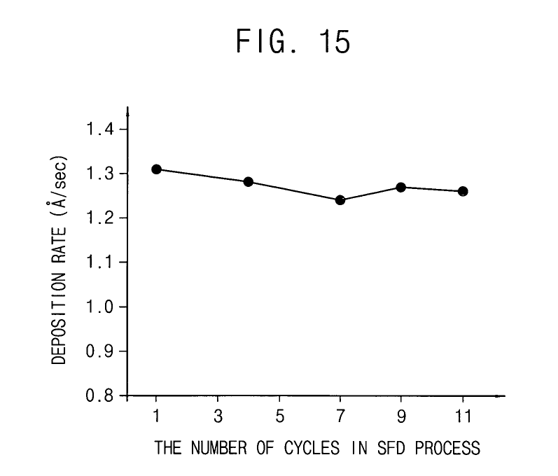

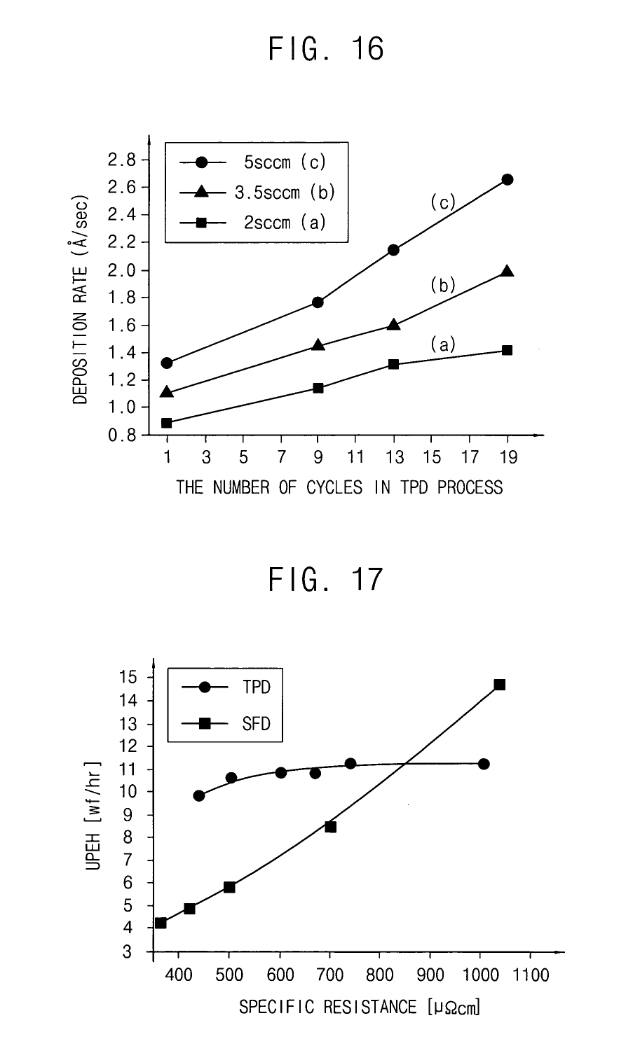

FIG. 15 is a graph showing a deposition rate of a titanium nitride layer relative to the number of cycles in the SFD process. FIG. 16 is a graph showing a deposition rate of a titanium nitride layer relative to the number of cycles in the TPD process. FIG. 17 is a graph showing unit per equipment hour (UPEH) relative to specific resistances of titanium layers formed using the SFD and the TPD processes.

In a conventional SFD process, a titanium nitride layer may be formed on a substrate loaded in a process chamber by providing a TiCl₄ gas and an NH₃ gas with flow rates of about 60 sccm, respectively, for about a first period of time. A nitrogen gas may be provided into a process chamber with at a flow rate of about 1,000 sccm for about a second period of time to purge an interior of the process chamber. The NH₃ gas may be provided onto the titanium nitride layer at a flow rate of about 1,000 sccm for about a third period of time so as to remove chlorine from the titanium nitride layer, and the nitrogen gas may be introduced into the process chamber at a flow rate of about 1,000 sccm for about a fourth period of time. The above-described process may be repeated to thereby form a titanium nitride layer having a thickness of about 150 Å. As shown in FIG. 15, the number of cycles including the above-described processes may be adjusted to obtain deposition rates for titanium nitride layers by the conventional SFD processes. In the conventional SFD process, the substrate may have a process temperature of about 500° C. and the process chamber may have a process pressure of about 3 Torr. The first, the second, the third, and the fourth period of times may be about six seconds, about 3 seconds, about 6 seconds, and about 3 seconds, respectively.

Referring to FIG. 15, the number of cycles to form the titanium nitride layer may not affect the deposition rate of the titanium nitride layer in the conventional SFD process, because the first source gas provided for the first period of time may be sufficiently removed from the process chamber by the nitrogen gas provided for the second period of time. In other words, the total amount of the first source gas to form the titanium nitride layer may not vary although the number of the cycles for forming the titanium nitride layer may increase. Hence, in the conventional SFD process, the deposition rate of the titanium nitride layer may be substantially constant when the number of the cycles to form the titanium nitride layer increases.

In a TPD process of example embodiments of the present invention, a TiCl₄ gas and an NH₃ gas may be provided onto a substrate at flow rates of about 60 sccm, respectively, for about a first period of time to thereby form a first titanium layer on the substrate. The TiCl₄ gas and the NH₃ gas may be provided onto the first titanium nitride layer to form a second titanium nitride layer on the first titanium nitride layer and simultaneously remove chlorine from the first and the second titanium nitride layers. Cycles including the above-described processes may be repeatedly carried out to form a titanium nitride layer having a thickness of about 150 Å on the substrate. As shown in FIG. 16, the number of cycles may include the above-described processes and may be adjusted to obtain deposition rates of the titanium nitride layers formed by the TPD processes according to example embodiments of the present invention. In the TPD process, the substrate may have a process temperature of about 500° C. and the process chamber may have a process pressure of about 2 Torr. The first and the second periods of time may be about 6 seconds and about 6 seconds, respectively. In addition, deposition rates of the titanium nitride layers may be measured when flow rates of the TiCl₄ gas provided for the second period of time may be about 3.5 sccm and about 5 sccm as shown in FIG. 16.

Referring to FIG. 16, the deposition rates of the titanium nitride layers may be gradually augmented in accordance with increases of the numbers of cycles including the above-described processes to form the titanium nitride layers when the flow rates of the TiCl₄ gas may be (a) about 2 sccm, (b) about 3.5 sccm, and (c) about 5 sccm. The first titanium nitride layer may be formed on the substrate by a surface reaction between the TiCl₄ gas and the NH₃ gas provided for the first period of time, and the second titanium nitride layer may be continuously formed on the first titanium nitride layer by a surface reaction and a mass transfer among the NH₃ gas provided at a relatively high flow rate, a residual TiCl₄ gas in the process chamber, and the TiCl₄ gas provided at a relatively low flow rate for the second period of time. Therefore, the deposition rates of the titanium nitride layers may gradually increase when the number of cycles increases.

Although the mass transfer may occur due to variations of the flow rates of the TiCl₄ gas and the NH₃ gas during the formation of the second titanium nitride layer, step coverage of the titanium nitride layer may not be deteriorated because the flow rate of the TiCl₄ gas provided for the second period of time may be considerably lower than that of the NH₃ gas, and the first and the second titanium nitride layers may be formed on the substrate. Further, since the process temperature and the process pressure may be relatively low, the mass transfer between the TiCl₄ gas and the NH₃ gas may be suppressed so that the titanium nitride layer may maintain good step coverage. As a result, the deposition rate of the titanium nitride layer may be greatly improved when the TiCl₄ gas may be provided for a time without deteriorating the step coverage of the titanium nitride layer.

Meanwhile, the deposition rate of the titanium nitride layer may be enhanced by adjusting the flow rate ratio between the TiCl₄ gas and the NH₃ gas provided at the second period of time irrespective of the process temperature and the process time. In example embodiments of the present invention, the deposition rate of the titanium nitride layer by the mass transfer may be substantially equal to the deposition rate of the titanium nitride layer by the surface reaction when the flow rate ratio between the TiCl₄ gas and the NH₃ gas may be in a range of about 1.0:100 to about 1.0:1,000.

Referring to FIG. 15, a manufacturing throughput of the titanium nitride layer may be consistent because the deposition rate of the titanium nitride layer may be substantially constant when the number of the cycles increases within a desired process time in the conventional SFD process. However, as shown in FIG. 17, the UPEH of the conventional SFD process may be greatly reduced when the feeding time of the NH₃ gas may be augmented to reduce the specific resistance of the titanium nitride layer, thereby considerably reducing the manufacturing throughput of the titanium nitride layer per unit time and unit apparatus to deposit a titanium nitride layer.

On the contrary, as shown in FIG. 16, a manufacturing throughput of a titanium nitride layer may increase because a deposition rate of a titanium nitride layer increases when a number of the cycles may be augmented within a desired process time in the TPD process accordingly to example embodiments of the present invention. Additionally, as shown in FIG. 17, the UPEH of the TPD process may not be substantially varied when the feeding time of the NH₃ gas may be augmented in order to reduce the specific resistance of the titanium nitride layer, thereby substantially maintaining the manufacturing throughput of the titanium nitride layer per unit time and unit apparatus for depositing a titanium nitride layer.

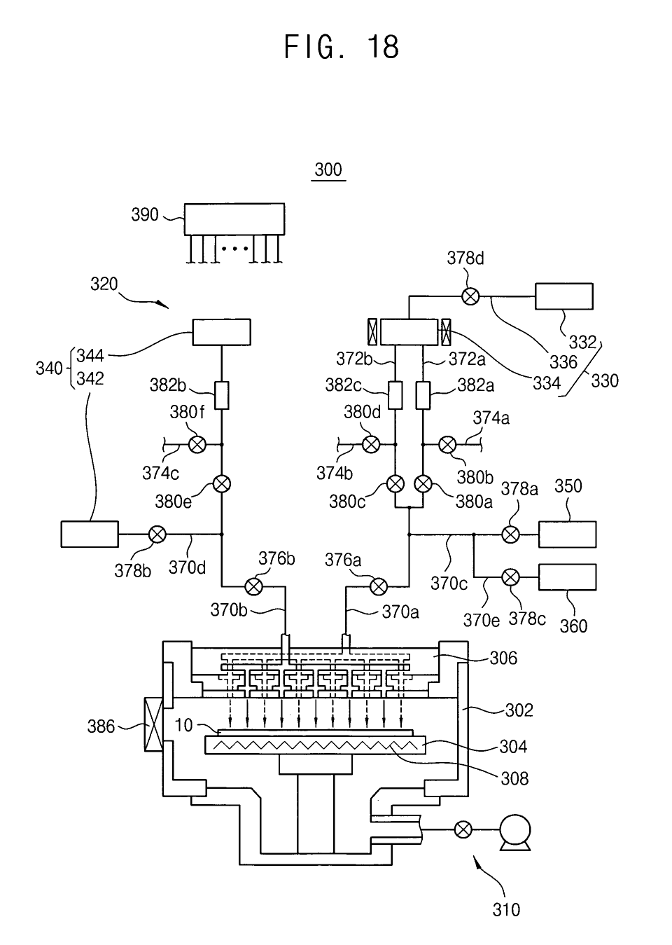

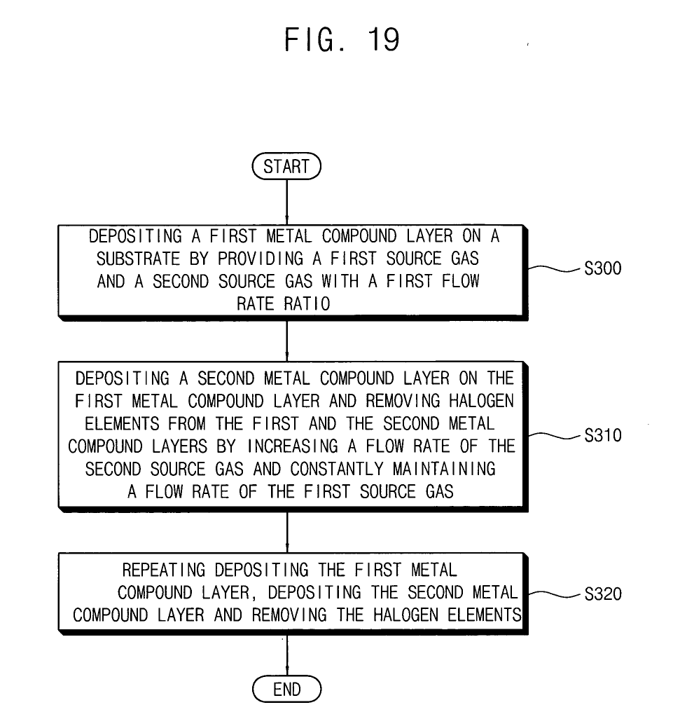

FIG. 18 is a cross-sectional view illustrating an apparatus for depositing a metal compound layer in accordance with another example embodiment of the present invention.

Referring to FIG. 18, an apparatus 300 to deposit a metal compound layer may be employed in a deposition process to form a metal composite layer for example, a titanium nitride layer on a substrate 10.

The apparatus 300 may include a process chamber 302, a stage 304, a vacuum system 310, and a gas supply system 320.

The stage 304 may support the substrate 10 in the process chamber 302, and the vacuum system 310 may maintain a pressure in an interior of the process chamber 302.

The gas supply system 320 may provide a first source gas and a second source gas onto the substrate 10 to form a metal composite layer on a substrate 10. The gas supply system 320 may be connected to a showerhead 306 disposed at an upper portion of the process chamber 302. The showerhead 306 may include a plurality of first nozzles and a plurality of second nozzles to uniformly spray the first and the second source gases onto the substrate 10 loaded on the stage 304.

The gas supply system 320 may provide the first and the second source gases onto the substrate 10 to form the metal composite layer on the substrate 10. The first source gas may include a metal and halogen elements. The second source gas may include nitrogen and hydrogen. To form a titanium nitride layer on the substrate 10, the first source gas may include a TiCl₄ gas and the second source gas may include an NH₃ gas. The first source gas and the second source gas may be introduced into the process chamber 302 by a first carrier gas and a second carrier gas, respectively.

The gas supply system 320 may further provide a purging gas and a cleaning gas into the process chamber 302 in order to purge and clean the inside of the process chamber 302. The purging gas may further serve as a pressure control gas to control/adjust a pressure of the interior of the process chamber 302.

The gas supply system 320 may include a first gas supply unit 330 to provide the first source gas (e.g., the TiCl₄ gas) and the first carrier gas, a second gas supply unit 340 to provide the second source gas (e.g., the NH₃ gas) and the second carrier gas, a third gas supply unit 350 to provide the purge gas, and a fourth gas supply unit 360 to provide the cleaning gas. The gas supply system 320 may be connected to the showerhead 306 through a plurality of connection lines.

The first gas supply unit 330 may include a first reservoir 332 to store the first carrier gas, a sealed container 334 to receive a first liquid source (e.g., liquid phase TiCl₄), and an immersed line 336 extending from the first reservoir 332 into the sealed container 334. The first source gas may be obtained from the first liquid source by bubbling the first carrier gas provided through the immersed line 336. In an example embodiment of the present invention, the first gas supply unit 330 may include a vaporizer.

The second gas supply unit 340 may include a second reservoir 342 to store the second carrier gas, and a second source gas tank 344 to provide the second source gas (e.g., the NH₃ gas).

The showerhead 306 and the sealed container 334 of the first gas supply unit 330 may be connected to each other through a first connection line 370a, a first divided line 372a, and a second divided line 372b. The first and the second divided lines 372a and 372b may be branched from the first connection line 370a. The showerhead 306 and the second source gas tank 344 of the second gas supply unit 340 may be connected to each other through a second connection line 370b. The third gas supply unit 350 may be connected to the first connection line 370a through a third connection line 370c. The second reservoir 342 of the second gas supply unit 340 may be connected to the second connection line 370b through a fourth connection line 370d. The fourth gas supply unit 360 may be connected to the third connection line 370c through a fifth connection line 370e so that the fourth gas supply unit 360 may introduce the cleaning gas into the process chamber 302 to clean the interior of the process chamber 302.

A first bypass line 374a, a second bypass line 374b, and a third bypass line 374c may be connected to the first divided line 372a, the second divided line 372b, and the first connection line 370a, respectively.

A first gate valve 376a and a second gate valve 376b may be installed in the first connection line 370a and the second connection line 370b, respectively. A first flow control valve 378a, a second flow control valve 378b, a third flow control valve 378c, and a fourth flow control valve 378d may be disposed in the third connection line 370c, the fourth connection line 370d, the fifth connection line 370e, and the immersed line 336, respectively.

A first interlocking valve 380a, a second interlocking valve 380b, a third interlocking valve 380c, a fourth interlocking valve 380d, a fifth interlocking valve 380e, and a sixth interlocking valve 380f may be disposed in the first divided line 372a, the first bypass line 374a, the second divided line 372b, the second bypass line 374d, the second connection line 370b, and the third bypass line 374c, respectively.

A first mass flow controller 382a may be disposed in the first divided line 372a in order to adjust a flow rate of the first source gas as a first flow rate. A second mass flow controller 382b may be installed in the second connection line 370b to adjust a flow rate of the second source gas as a second flow rate. In addition, a third mass flow controller 382c may be installed in the second divided line 372b in order to adjust a flow rate of the first source gas as a third flow rate.

While the first source gas and the second source gas may be provided onto a substrate 10 at the first flow rate and the second flow rate in order to deposit a first metal compound layer on the substrate 10, the first and the fifth interlocking valves 380a and 380e may be opened, whereas the second and the sixth interlocking valves 380b and 380f may be closed. At the same time, to bypass the first source gas with the third flow rate, the third interlocking valve 380c may be closed but the fourth interlocking valve 380d may be opened.

After the formation of the first metal compound layer on the substrate 10, the third and the fifth interlocking valves 380c and 380e may be opened, whereas the fourth and the sixth interlocking valves 380d and 380f may be closed while the first source gas and the second source gas may be introduced into the process chamber 302 at the third flow rate and the second flow rate, respectively. Simultaneously, the first interlocking valve 380a may be closed and the second interlocking valve 380b may be opened in order to bypass the first source gas with the first flow rate. Thus, a second metal compound layer may be continuously deposited on the first metal compound layer, and undesired materials for example, chlorine are simultaneously removed from the first and the second metal compound layers in accordance with a reaction between the second source gas provided at the second flow rate, the first source gas provided at the third flow rate, and a residual first source gas in the process chamber 302 after the formation of the first metal compound layer.

A valve control unit 390 may adjust operations of the first to the sixth interlocking valves 380a, 380b, 380c, 380d, 380e, and 380f, operations of the first and the second gate valves 376a and 376b, and performances of the first to the fourth flow control valves 378a, 378b, 378c, and 378d.

The stage 304 may include a heater 308 to heat the substrate 10 to a process temperature. A gate door 386 may be provided at a sidewall of the process chamber 302 to load and unload the substrate 10 into the process chamber 302. Reaction byproducts generated during the formation of the metal composite layer and residual gases may be removed from the process chamber 302 by the vacuum system 310 coupled to the process chamber 302.

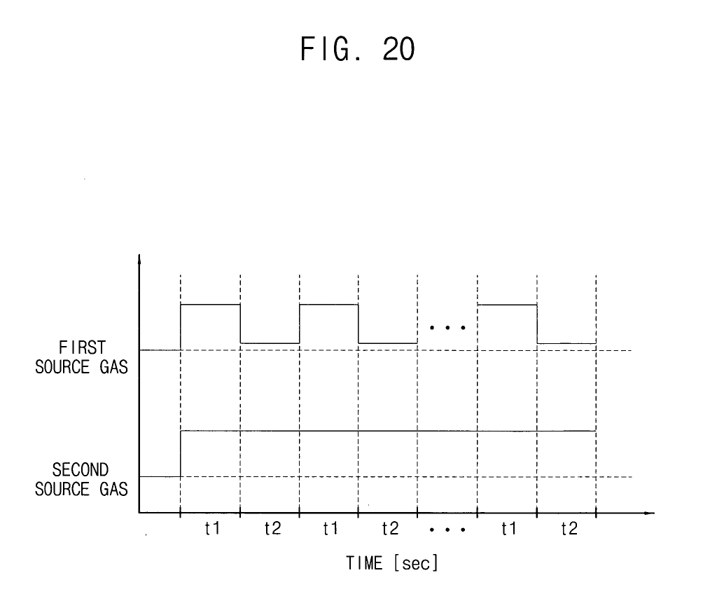

FIG. 19 is a flow chart illustrating a method of depositing a metal compound layer on a substrate using the apparatus of FIG. 18 in accordance with an example embodiment of the present invention. FIG. 20 is a timing diagram illustrating feeding times of source gases used in the method illustrated in FIG. 19.

Referring to FIGS. 18 to 20, in S300, a first metal compound layer may be deposited on a substrate 10 for example, a silicon wafer by providing a first source gas and a second source gas onto the substrate 10. The first and the second source gases may be provided onto the substrate 10 at a first flow rate ratio. The first source gas may include a metal and halogen elements. The second source gas may include a first material capable of reacting with the metal in the first source gas, and a second material capable of reacting with the halogen element in the first source gas. For example, the first source gas may include a TiCl₄ gas, and the second source gas may include an NH₃ gas.

During the formation of the first metal compound layer, first and second mass flow controllers 382a and 382b may adjust flow rates of the first and the second source gases. For example, the first flow rate ratio between the first flow rate of the first source gas and the second flow rate of the second source gas may be in a range of about 1.0:0.5 to about 1.0:10. The first flow rate ratio may be about 1.0:1.0 to deposit the first metal compound layer by a surface reaction between the first and the second source gases. For example, the first flow rate of the first source gas may be about 60 sccm, and also the second flow rate of the second source gas may be about 60 sccm.

In S310, a second metal compound layer may be deposited on the first metal compound layer by providing the first source gas and the second source gas onto the substrate 10. Simultaneously, undesired materials may be removed from the first and the second metal compound layers. The first and the second source gases may be provided at a second flow rate ratio substantially different from the first flow rate ratio. Particularly, the first source gas may be provided at a third flow rate substantially lower than the first flow rate, whereas the flow rate of the second source gas may be constantly maintained. That is, the second source gas may be provided at the second flow rate. In an example embodiment of the present invention, a flow rate ratio between the third flow rate of the first source gas and the second flow rate of the second source gas may be above about 1.0:100. The third mass flow controller 382c may adjust the third flow rate of the first source gas.

In S320, a metal composite layer having a desired thickness may be formed on the substrate 10 by repeating S300 and S310. Namely, a first process of depositing a first metal compound layer and a second process of depositing a second metal compound layer may be carried out, thereby forming the metal composite layer on the substrate 10.

As shown in FIG. 20, in S300, the first source gas may be provided onto the substrate 10 at the first flow rate for a first period of time t1, and the second source gas may be introduced onto the substrate 10 with the second flow rate for the first period of time t1. In S310, the first source gas may be provided onto the first metal compound layer with the third flow rate for a second period of time t2, and the second source gas may be introduced onto the first metal compound layer with the second flow rate for the second period of time t2.

In S300 and S310, the substrate 10 may have a process temperature of about 400° C. to about 600° C. and the process chamber 302 may have a process pressure of about 0.1 Torr to about 2.5 Torr. For example, the substrate 10 may have a process temperature of about 500° C. and the process chamber 302 may have a process pressure of about 2.0 Torr.

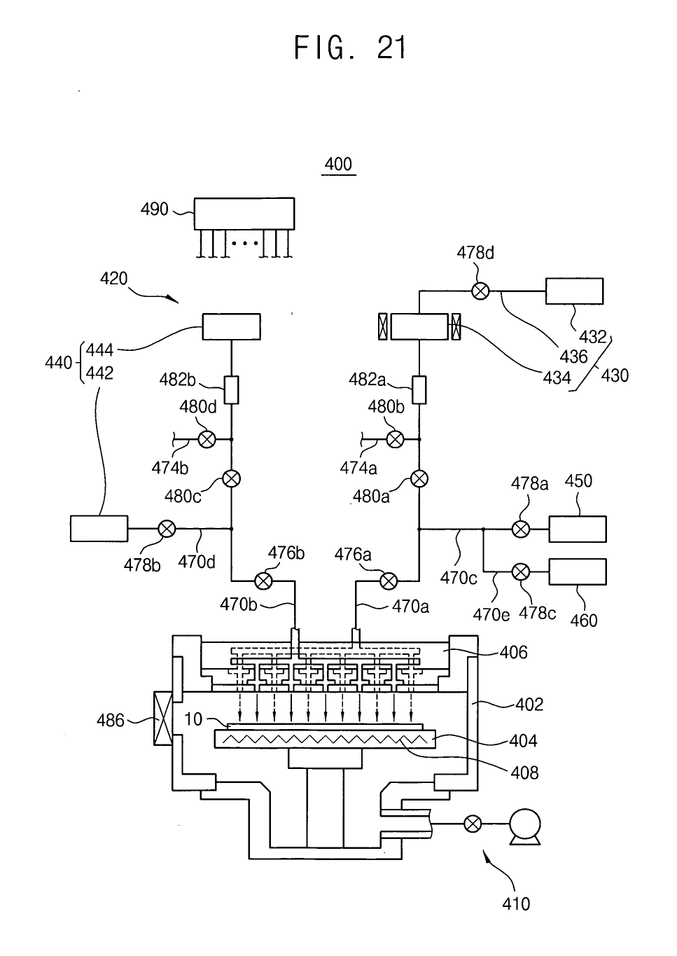

FIG. 21 is a cross-sectional view illustrating an apparatus for depositing a metal compound layer in accordance with another example embodiment of the present invention.

Referring to FIG. 21, an apparatus 400 to deposit a metal compound layer may be used in a deposition process to form a metal composite layer for example, a titanium nitride layer on a substrate 10.

The apparatus 400 may include a process chamber 402, a stage 404, a vacuum system 410, and a gas supply system 420.

The stage 404 may support the substrate 10 in the process chamber 402, and the vacuum system 410 may maintain a pressure in an interior of the process chamber 402.

The gas supply system 420 may provide a first source gas and a second source gas onto the substrate 10 in order to form the metal composite layer on the substrate 10. The gas supply system 420 may be connected to a showerhead 406 disposed at an upper portion of the process chamber 402. The showerhead 406 may include a plurality of first nozzles and a plurality of second nozzles to uniformly spray the first and the second source gases onto the substrate 10 supported by the stage 404.

The gas supply system 420 may provide the first and the second source gases onto the substrate 10 to form the metal composite layer on the substrate 10. The first source gas may include a metal and halogen elements, and the second source gas may include nitrogen and hydrogen. For example, the first source gas may include a TiCl₄ gas and the second source gas may include an NH₃ gas, if the titanium nitride layer is formed on the substrate 10. The first source gas and the second source gas may be carried into the process chamber 402 using a first carrier gas and a second carrier gas, respectively. The gas supply system 420 may further provide a purging gas and a cleaning gas into the process chamber 402 in order to purge and to clean an interior of the process chamber 402. The purging gas may additionally serve as a pressure control gas to adjust/control a pressure of the interior of the process chamber 402.

The gas supply system 420 may include a first gas supply unit 430 to provide the first source gas (e.g., the TiCl₄ gas) and the first carrier gas, a second gas supply unit 440 to provide the second source gas (e.g., the NH₃ gas) and the second carrier gas, a third gas supply unit 450 to provide the purging gas, and a fourth gas supply unit 460 to provide the cleaning gas. The gas supply system 420 may be connected to the showerhead 406 through a plurality of connection lines.

The first gas supply unit 430 may have a first reservoir 432 to store the first carrier gas, a sealed container 434 to store a first liquid source (e.g., liquid phase TiCl₄), and an immersed line 436 extending from the first reservoir 432 into the sealed container 434. The first source gas may be obtained from the first liquid source by bubbling the first carrier gas provided through the immersed line 436. In an example embodiment of the present invention, the first gas supply unit 430 may include a vaporizer. The second gas supply unit 440 may include a second reservoir 442 to store the second carrier gas, and a second source gas tank 444 to provide the second source gas (e.g., the NH₃ gas).

A first connection line 470a may connect the showerhead 406 to the sealed container 434, and a second connection line 470b may connect the showerhead 406 to the second source gas tank 444. The third gas supply unit 450 may be connected to the first connection line 470a through a third connection line 470c, and the second reservoir 442 of the second gas supply unit 440 may be connected to the second connection line 470b through a fourth connection line 470d. The fourth gas supply unit 460 may be connected to the third connection line 470c through a fifth connection line 470e to provide cleaning gas into the process chamber 402 to clean the interior of the process chamber 402.

A first bypass line 474a and a second bypass line 474b may be connected to the first connection line 470a and the second connection line 470b, respectively.

A first gate valve 476a and a second gate valve 476b may be respectively disposed in the first connection line 470a and the second connection line 470b. A first flow control valve 478a, a second flow control valve 478b, a third flow control valve 478c, and a fourth flow control valve 478d may be installed in the third connection line 470c, the fourth connection line 470d, the fifth connection line 470e, and the immersed line 436, respectively. A first interlocking valve 480a, a second interlocking valve 480b, a third interlocking valve 480c, and a fourth interlocking valve 480d may be disposed in the first connection line 470a, the first bypass line 474a, the second connection line 470b, and the second bypass line 474d, respectively.

A first mass flow controller 482a may be disposed in the first connection line 470a to adjust a flow rate of the first source gas at a first flow rate. A second mass flow controller 482b may be installed in the second connection line 470b to thereby adjust a flow rate of the second source gas at a second flow rate.

While the first source gas and the second source gas may be provided onto the substrate 10 at the first flow rate and the second flow rate in order to deposit a first metal compound layer on the substrate 10, the first and the third interlocking valves 480a and 480c may be opened but the second and the fourth interlocking valves 480b and 480d may be closed.

After forming the first metal compound layer, the third interlocking valve 480c may be opened and the fourth interlocking valve 480d may be closed while a supply of the first source gas may be stopped and the second source gas may be provided onto the first metal compound layer with the second flow rate. At the same time, the first interlocking valve 480a may be closed but the second interlocking valve 480b may be opened in order to bypass the first source gas with the first flow rate. Accordingly, a second metal compound layer may be continuously deposited on the first metal compound layer, and undesired materials for example, chlorine may be simultaneously removed from the first and the second metal compound layers in accordance with a reaction between the second source gas provided at the second flow rate and a residual first source gas in the process chamber 402 after the formation of the first metal compound layer.

A valve control unit 490 may control operations of the first to the fourth interlocking valves 480a, 480b, 480c, and 480d, performances of the first and the second gate valves 476a and 476b, and operations of the first to the fourth flow control valves 478a, 478b, 478c, and 478d.

The stage 404 may include a heater 408 to heat the substrate 10 to a process temperature. A gate door 486 may be disposed at a sidewall of the process chamber 402 to load and unload the substrate 10 from the process chamber 402. Reaction byproducts generated in the formation of the metal composite layer and residual gases may be removed from the process chamber 402 using the vacuum system 410 coupled to the process chamber 402.

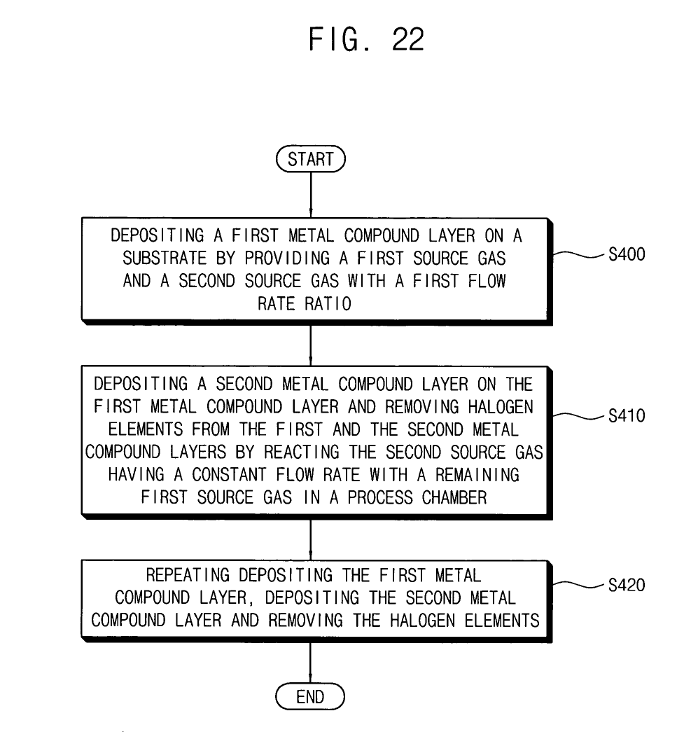

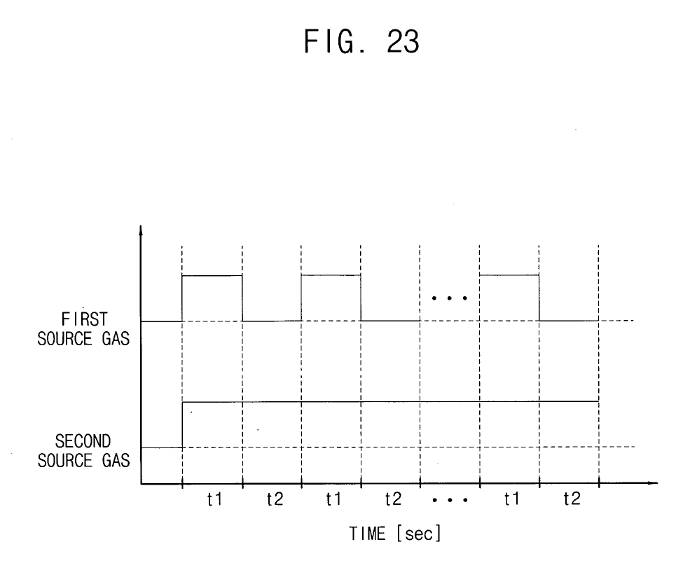

FIG. 22 is a flow chart illustrating a method of depositing a metal compound layer on a substrate using the apparatus of FIG. 21 in accordance with an example embodiment of the present invention. FIG. 23 is a timing diagram illustrating feeding times of source gases used in the method illustrated in FIG. 22.

Referring to FIGS. 21 to 23, in S400, a first metal compound layer may be deposited on a substrate 10 by providing a first source gas and a second source gas onto the substrate 10 at a first flow rate ratio. The first source gas may include a metal and halogen elements, and the second source gas may include a first material capable of reacting with the metal in the first source gas and a second material capable of reacting with the halogen element in the first source gas. For example, the first source gas may include a TiCl₄ gas, and the second source gas may include an NH₃ gas.

During the formation of the first metal compound layer, first and the second mass flow controllers 482a and 482b may independently adjust the first flow rate of the first source gas and the second flow rate of the second source gas. For example, the first flow rate ratio may be in a range of about 1.0:0.5 to about 1.0:10. The first flow rate ratio may be about 1.0:1.0 in order to deposit the first metal compound layer by a surface reaction between the first and the second source gases. For example, the first flow rate of the first source gas may be about 60 sccm, and also the second flow rate of the second source gas may be about 60 sccm.

In S410, the supply of the first source gas may be ceased and the second source gas may be provided onto the first metal compound layer at a second flow rate so that the second metal compound layer may be deposited on the first metal compound layer by a reaction between the second source gas provided at a constant flow rate and a residual first source gas in a process chamber 402. Simultaneously, undesired materials may be removed from the first and the second metal compound layers by a reaction between the second source gas and the residual first source gas.

In S420, the metal composite layer having a desired thickness may be formed on the substrate 10 by repeating in series the processes of S400 and S410. Namely, a first process of depositing a first metal compound layer and a second process of depositing a second metal compound layer may be carried out in order to thereby form the metal composite layer on the substrate 10.

In S400 and as shown in FIG. 23, the first source gas may be provided onto the substrate 10 at the first flow rate for a first period of time t1, and the second source gas may be introduced onto the substrate 10 with the second flow rate for the first period of time t1. In S410, the supply of the first source gas may be stopped and the second source gas may be provided onto the first metal compound layer with the second flow rate for a second period of time t2. The first source gas provided in S400 may remain in the process chamber 402 after the formation the first metal compound layer. The second metal compound layer may be continuously deposited on the first metal compound layer by a reaction between the residual first source gas and the second source gas which may be provided at a constant flow rate. In an example embodiment of the present invention, the first source gas (e.g., the TiCl₄ gas) may be intermittently introduced into the process chamber 402 at a flow rate of about 60 sccm in processes S400 and S410. Additionally, the second source gas (e.g., the NH₃ gas) may be introduced into the process chamber 402 at a constant flow rate of about 60 sccm in processes S400 and S410.

In particular, although a first interlocking valve 480a may stop the supply of the first source gas in S410, the residual first source gas provided in S400 may react with the second source gas provided in S410 so that the second metal compound layer may be continuously deposited on the first metal compound layer. If the second period of time t2 of S410 is substantially shorter than a time required to completely exhaust the first source gas from the process chamber 402, the first flow rate of the first source gas in the formation of the second metal compound layer may be gradually reduced. If the second period of time t2 of S410 is sufficiently long, the first flow rate of the first source gas in the formation of the second metal compound layer may be gradually reduced. The first residual source gas may be completely consumed after the formation of the second metal compound layer.

In S400 and S410, the substrate 10 may have a process temperature of about 400° C. to about 600° C. and the process chamber 402 may have a process pressure of about 0.1 Torr to about 2.5 Torr. For example, the substrate 10 may have a process temperature of about 500° C. and the process chamber 402 may have a process pressure of about 2.0 Torr.

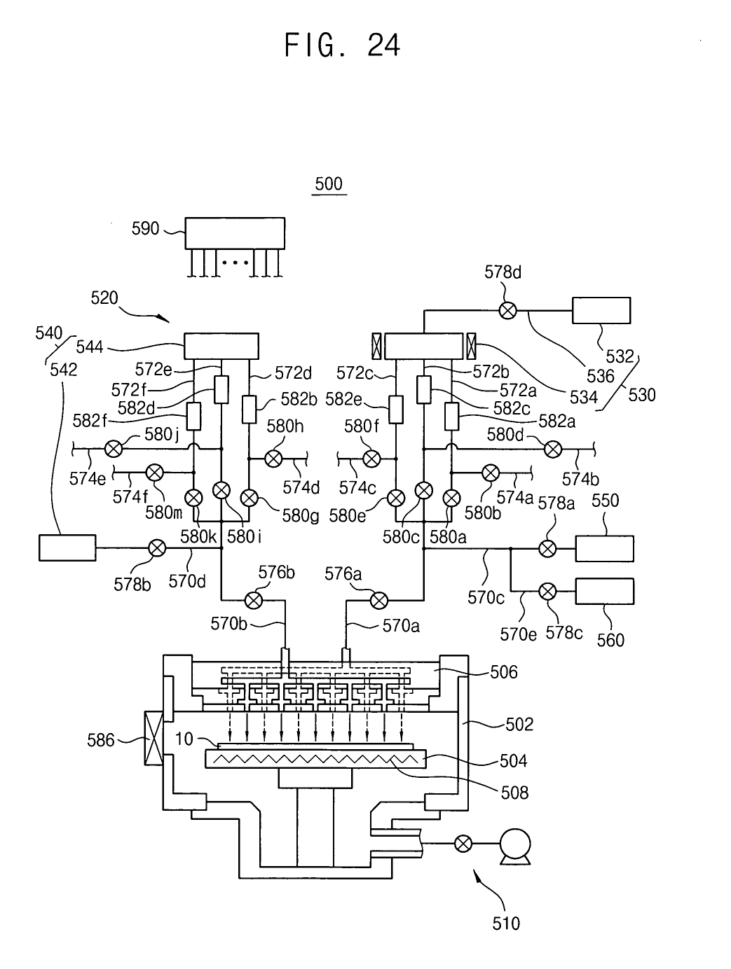

FIG. 24 is a cross-sectional view illustrating an apparatus for depositing a metal compound layer in accordance with an example embodiment of the present invention.

Referring to FIG. 24, an apparatus 500 to deposit a metal compound layer may be employed in a deposition process to form a metal composite layer for example, a titanium nitride layer on a semiconductor substrate 10. The apparatus 500 may include a process chamber 502, a stage 504, a vacuum system 510, and a gas supply system 520.

The gas supply system 520 may provide a first source gas and a second source gas onto the substrate 10 loaded in the process chamber 502 in order to form the metal composite layer on the substrate 10. The gas supply system 520 may be connected to a showerhead 506 disposed at an upper portion of the process chamber 502.

A first source gas may include a TiCl₄ gas and a second source gas may include an NH₃ gas if a titanium nitride layer is formed on the substrate 10. The first source gas and the second source gas may be carried into the process chamber 502 using a first carrier gas and a second carrier gas, respectively. The gas supply system 520 may further provide a purging gas and a cleaning gas into the process chamber 502 so as to purge and to clean an interior of the process chamber 502, respectively.

The gas supply system 520 may include a first gas supply unit 530 to provide the first source gas (e.g., the TiCl₄ gas) and the first carrier gas, a second gas supply unit 540 to provide the second source gas (e.g., the NH₃ gas) and the second carrier gas, a third gas supply unit 550 to provide the purging gas, and a fourth gas supply unit 560 to provide the cleaning gas. The gas supply system 520 may be connected to the showerhead 506 through a plurality of connection lines.

The first gas supply unit 530 may have a first reservoir 532 to store the first carrier gas, a sealed container 534 to store a first liquid source (e.g., liquid phase TiCl₄), and an immersed line 536 extending from the first reservoir 532 into the sealed container 534. The first source gas may be obtained from the first liquid source by bubbling the first carrier gas provided through the immersed line 536. The second gas supply unit 540 may include a second reservoir 542 to store the second carrier gas, and a second source gas tank 544 to provide the second source gas (e.g., the NH₃ gas).

The showerhead 506 may be connected to the sealed container 534 of the first gas supply unit 530 through a first connection line 570a, a first divided line 572a, a second divided line 572b, and a third divided line 572c. The first to the third divided lines 572a, 572b, and 572c may be branched from the first connection line 570a. The showerhead 506 may be connected to the second source gas tank 544 of the second gas supply unit 540 through a second connection line 570b, a fourth divided line 572d, a fifth divided line 572e, and a sixth divided line 572f. The fourth to the sixth divided lines 572d, 572e, and 572f may be branched from the second connection line 570b. The third gas supply unit 550 may be connected to the first connection line 570a through a third connection line 570c. The second reservoir 542 of the second gas supply unit 540 may be connected to the second connection line 570b through a fourth connection line 570d. The fourth gas supply unit 560 may be connected to the third connection line 570c through a fifth connection line 570e to provide the cleaning gas into the process chamber 502 to clean the interior of the process chamber 502.

A first bypass line 574a, a second bypass line 574b, a third bypass line 574c, a fourth bypass line 574d, a fifth bypass line 574e, and a sixth bypass line 574f may be connected to the first divided line 572a, the second divided line 572b, the third divided line 572c, the fourth divided line 572d, the fifth divided line 572e, and the sixth divided line 572f, respectively.

A first gate valve 576a and a second gate valve 576b may be respectively disposed in the first connection line 570a and the second connection line 570b. A first flow control valve 578a, a second flow control valve 578b, a third flow control valve 578c, and a fourth flow control valve 578d may be installed in the third connection line 570c, the fourth connection line 570d, the fifth connection line 570e, and the immersed line 536, respectively. A first interlocking valve 580a, a second interlocking valve 580b, a third interlocking valve 580c, a fourth interlocking valve 580d, a fifth interlocking valve 580e, a sixth interlocking valve 580f, a seventh interlocking valve 580g, an eighth interlocking valve 580h, a ninth interlocking valve 580i, a tenth interlocking valve 580j, an eleventh interlocking valve 580k, and a twelfth interlocking valve 580m may be disposed in the first divided line 572a, the first bypass line 574a, the second divided line 572b, the second bypass line 574b, the third divided line 572c, the third bypass line 574c, the fourth divided line 572d, the fourth bypass line 574d, the fifth divided line 572e, the fifth bypass line 574e, the sixth divided line 572f, and the sixth bypass line 574f, respectively.

A first mass flow controller 582a may be disposed in the first divided line 572a to adjust a flow rate of the first source gas at a first flow rate. A second mass flow controller 582b may be installed in the fourth divided line 572d to thereby adjust a flow rate of the second source gas at a second flow rate. A third mass flow controller 582c may be disposed in the second divided line 572b to adjust a flow rate of the first source gas at a third flow rate. A fourth mass flow controller 582d may be installed in the fifth divided line 572e to adjust a flow rate of the second source gas at a fourth flow rate. A fifth mass flow controller 582e may be disposed in the third divided line 572c to adjust a flow rate of the first source gas at a fifth flow rate. A sixth mass flow controller 582f may be installed in the sixth divided line 572f so at to adjust a flow rate of the second source gas at a sixth flow rate.

While the first source gas and the second source gas may be provided onto the substrate 10 at the first flow rate and the second flow rate in order to deposit a first metal compound layer on the substrate 10, the first and the seventh interlocking valves 580a and 580g may be opened, whereas the second and the eighth interlocking valves 580b and 580h may be closed. Simultaneously, the third and the fifth interlocking valves 580c and 580e may be closed and the fourth and the sixth interlocking valves 580d and 580f may be opened so as to bypass the first source gas with the third and the fifth flow rates. Further, to bypass the second source gas with the fourth and the sixth flow rates, the ninth and the eleventh interlocking valves 580i and 580k may be closed but the tenth and the twelfth interlocking valves 580j and 580m may be opened.

After the formation of the first metal compound layer, the third and the ninth interlocking valves 580c and 580i may be opened, whereas the fourth and the tenth interlocking valves 580d and 580j may be closed while the first and the second source gases may be provided onto the first metal compound layer with the third and the fourth flow rates in order to form a second metal compound layer. At the same time, the first and the fifth interlocking valves 580a and 580e may be closed but the second and the sixth interlocking valves 580b and 580f may be opened so as to bypass the first source gas with the first and the fifth flow rates. Additionally, the seventh and the eleventh interlocking valves 580g and 580k may be closed, whereas the eighth and the twelfth interlocking valves 580h and 580m may be opened so as to bypass the second source gas with the second and the sixth flow rates.

After depositing the second metal compound layer, the fifth and the eleventh interlocking valves 580e and 580k may be opened but the sixth and the twelfth interlocking valves 580f and 580m may be closed while the first and the second source gases may be provided onto the second metal compound layer with the fifth and the sixth flow rates so as to form a third metal compound layer. Simultaneously, the first and the third interlocking valves 580a and 580c may be closed, whereas the second and the fourth interlocking valves 580b and 580d may be opened in order to bypass the first source gas with the first and the third flow rates. In addition, the seventh and the ninth interlocking valves 580g and 580i may be closed but the eighth and the tenth interlocking valves 580h and 580j may be opened so as to bypass the second source gas with the second and the fourth flow rates.

After the formation of the third metal compound layer, the third and the ninth interlocking valves 580c and 580i may be opened but the fourth and the tenth interlocking valves 580d and 580j may be closed while the first and the second source gases may be provided onto the third metal compound layer with the third and the fourth flow rates so as to form a fourth metal compound layer on the third metal compound layer. Simultaneously, the first and the fifth interlocking valves 580a and 580e may be closed but the second and the sixth interlocking valves 580b and 580f may be opened in order to bypass the first source gas with the first and the fifth flow rates. Additionally, the seventh and the eleventh interlocking valves 580g and 580k may be closed, whereas the eighth and the twelfth interlocking valves 580h and 580m may be opened to bypass the second source gas with the second and the sixth flow rates.

A valve control unit 590 may control operations of the first to the twelfth interlocking valves 580a, 580b, 580c, 580d, 580e, 580f, 580g, 580h, 580i, 580j, 580k, and 580m, operations of the first and the second gate valves 576a and 576b, and performances of the first to the fourth flow control valves 578a, 578b, 578c, and 578d.

The stage 504 may include a heater 508 to apply heat to the substrate 10 to a process temperature. A gate door 586 may be disposed at a sidewall of the process chamber 502 so that the substrate 10 may be loaded/unloaded into/from the process chamber 502 through the gate door 586. The vacuum system 510 coupled to the process chamber 502 may remove reaction byproducts generated during the formation of the metal deposit layer and residual gases in the process chamber 502.

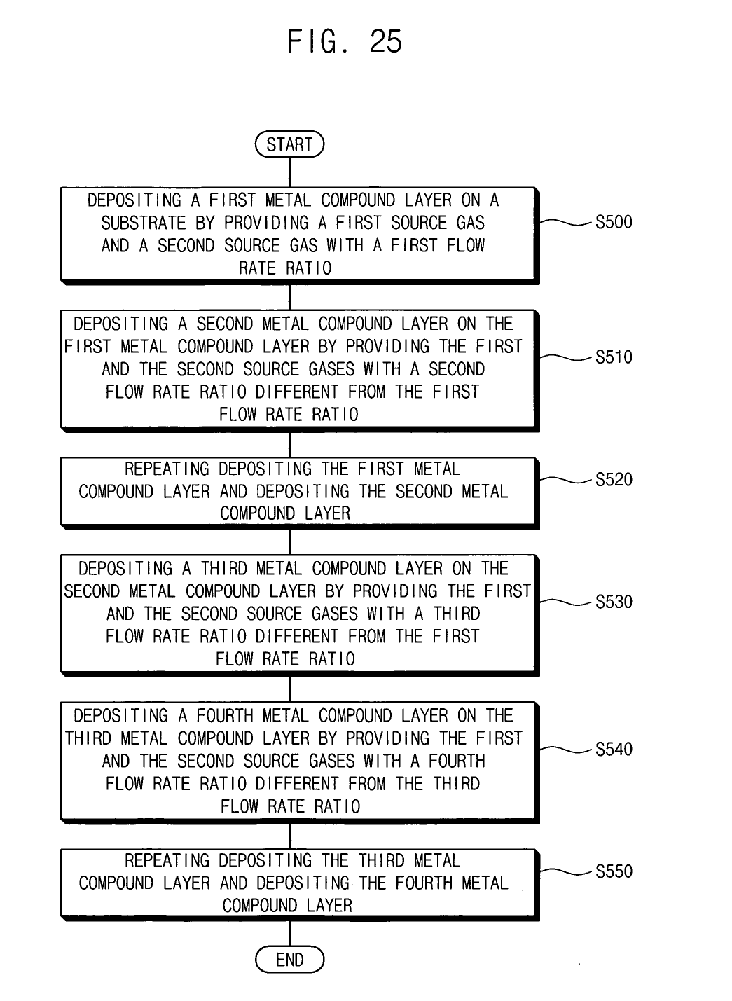

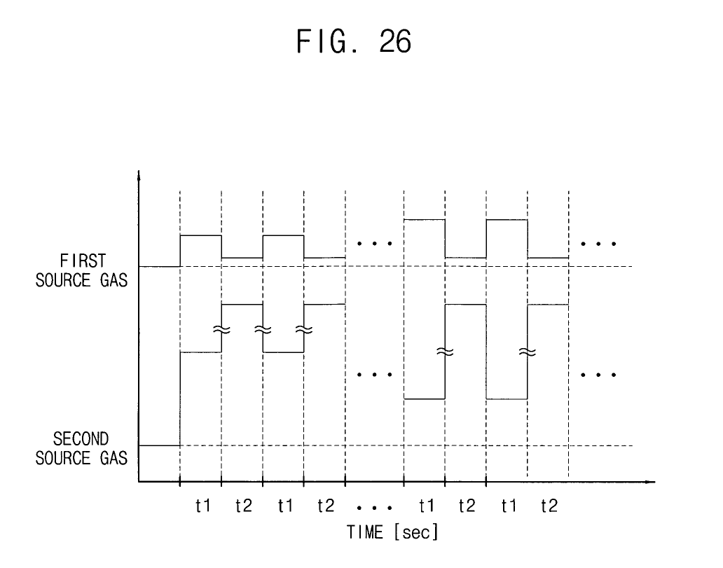

FIG. 25 is a flow chart illustrating a method of depositing a metal compound layer on a substrate using the apparatus illustrated FIG. 24 in accordance with an example embodiment of the present invention. FIG. 26 is a timing diagram illustrating feeding times of source gases used in the method illustrated in FIG. 25.

Referring to FIGS. 24 to 26, in S500, a first metal compound layer may be deposited on a substrate 10 by providing a first source gas and a second source gas onto the substrate 10 at a first flow rate ratio. The first source gas may include a metal and halogen elements, and the second source gas may include a first material capable of reacting with the metal in the first source gas and a second material capable of being reacted with the halogen element in the first source gas. For example, the first source gas may include a TiCl₄ gas, and the second source gas may include an NH₃ gas.

In the deposition of the first metal compound layer, first and second mass flow controllers 582a and 582b may independently adjust a first flow rate of the first source gas and a second flow rate of the second source gas, respectively. A first flow rate ratio between the first flow rate of the first source gas and the second flow rate of the second source gas may be determined within a range in which the first metal compound layer may be deposited by a surface reaction between the first and the second source gases rather than the mass transfer between the first and the second source gases.

In an example embodiment of the present invention, the first flow rate ratio between the first and the second flow rates of the first and the second source gases may be in a range of about 1.0:2.0 to about 1.0:10. In other words, the first flow rate may be in a range of about 0.1:1.0 to about 0.5:1.0. Thus, undesired materials for example, chlorine may be effectively removed from the first metal compound layer because the second flow rate of the second source gas may be relatively lower than the first flow rate of the first source gas. For example, the first flow rate of the first source gas may be about 20 sccm adjusted by the first mass flow controller 582a, and the second flow rate of the second source gas may be about 60 sccm adjusted by the second mass flow controller 582b.

In S510, the first and the second source gases may be provided onto the first metal compound layer at a second flow rate ratio substantially different from the first flow rate. Accordingly, the second metal compound layer may be deposited on the first metal compound layer by a reaction between the first and the second source gases, and undesired materials may be simultaneously removed from the first and the second metal compound layers.

In an example embodiment of the present invention, the first source gas may be provided at a third flow rate substantially lower than the first flow rate, and the second source gas may be provided at a fourth flow rate substantially higher than the second flow rate. The third mass flow controller 582c may adjust the third flow rate of the first source gas, and the fourth mass flow controller 582d may adjust the fourth flow rate of the second source gas. For example, the second flow rate ratio between the third flow rate and the fourth flow rate may be in a range of about 1.0:100 to about 1.0:1,000 to sufficiently remove the undesired materials from the first and the second metal compound layers. In other words, the second flow rate ratio may be in a range of about 0.001:1.0 to about 0.01:1.0. During the formation of the second metal compound layer, the first source gas may be provided at the third flow rate of about 2.0 sccm, and the second source gas may be provided at a flow rate of about 1,000 sccm. In an example embodiment of the present invention, a flow rate ratio between the second and the fourth flow rates may be in a range of about 1.0:10 to about 1.0:100.

In S520, a first metal composite layer having a desired thickness may be formed on the substrate 10 by repeating in series the processes of S500 and S510. The first metal composite layer may include the first and the second metal compound layers.

In S530, the third metal compound layer may be deposited on the first metal composite layer by providing the first and the second source gases with a third flow rate ratio substantially different from the second flow rate ratio. The fifth mass flow controller 582e may adjust the fifth flow rate of the first source gas, and the sixth mass flow controller 582f may adjust the sixth flow rate of the second source gas. The third flow rate ratio between the fifth and the sixth flow rates may be in a range of about 1.0:0.5 to about 1.0:2.0. In an example embodiment of the present invention, the third flow rate ratio between the fifth and the sixth flow rates may be about 1.0:1.0 in order to advantageously deposit the third metal compound layer by a surface reaction between the first and the second source gases. For example, the fifth flow rate of the first source gas may be about 30 sccm, and the sixth flow rate of the second source gas may be about 30 sccm.

In S540, a fourth metal compound layer may be continuously deposited on the third metal compound layer, and undesired materials contained in the third and the fourth metal compound layers may be simultaneously removed by providing the first and the second source gases with a fourth flow rate ratio substantially different from the third flow rate ratio. The first source gas and the second source gas may be supplied with a seventh flow rate and an eighth flow rate, respectively.

In an example embodiment of the present invention, the fourth flow rate ratio may be substantially equal to the second flow rate ratio. Since the third mass flow controller 582c and the fourth mass flow controller 582d may adjust the seventh flow rate and the eighth flow rate, the fourth flow rate ratio between the seventh and the eighth flow rates may be in a range of about 1.0:100 to about 1.0:1,000.

In S550, a second metal composite layer having a desired thickness may be formed on the first metal composite layer by repeating in series the processes of S530 and S540. The second metal composite layer may include the third and the fourth metal compound layers.

During the formation of the first metal composite layer, the halogen elements may chemically react with materials contained in an underlying layer to thereby generate reaction byproducts that deteriorate electrical characteristics of the underlying layer. To prevent the electrical characteristics of the underlying layer from deteriorating, the first flow rate of the first source gas may be substantially lower than the second flow rate of the second source gas used during the formation of the first composite layer.

If the second metal composite layer is formed on the first metal composite layer, the first metal composite layer may prevent the reaction between the halogen elements and the materials contained in the underlying layer so that the fifth flow rate of the first source gas becomes substantially greater than the first flow rate of the first source gas. Accordingly, the second metal composite layer may be uniformly formed on the first metal composite layer by the surface reaction between the first and the second source gases.

In example embodiments of the present invention, the process temperature and the process pressure may be relatively low during the formation of the first metal composite layer. The mass transfer between the source gases may be suppressed at a relatively low process temperature and pressure as shown in FIGS. 5 and 6 so that the first metal composite layer may have good step coverage, and also a thermal stress applied to the underlying layer may decrease. Further, the reaction between the halogen elements and the material in the underlying layer may be suppressed at a relatively low process temperature, and a residual time of the first source gas in the process chamber 502 may be reduced, thereby suppressing the reaction between the halogen elements and the material in the underlying layer. The process temperature may be in a range of about 400 to about 600° C. and the process pressure may be in a range of about 0.1 to about 2.5 Torr during the formation of the first metal composite layer. For example, the process temperature may be about 500° C. and the process pressure may be about 2.0 Torr.

In example embodiments of the present invention, the second metal composite layer may be formed at a process temperature and a process pressure substantially similar to those of the first metal composite layer.

In example embodiments of the present invention, the underlying layer may include a dielectric layer of a capacitor, a gate insulation layer of a transistor, a blocking oxide layer of a non-volatile semiconductor device, etc. If the underlying layer includes a high-k material for example, hafnium oxide (HfO₂) or zirconium oxide (ZrO₂), generations of reaction byproducts including hafnium chloride (HfCl₄) or zirconium chloride (ZrCl₄) may be suppressed to thereby greatly reduce resistance of the underlying layer and a leakage current from the underlying layer.

As shown in FIGS. 5 and 7, the metal composite layer may have desired step coverage by adjusting one of a process temperature and a process pressure when only the step coverage of the metal composite layer is considered. If the first metal composite layer is formed at a relatively high process pressure of about 5 Torr and a relatively low process temperature of about 500° C., the first metal composite layer may have excellent step coverage and the thermal stress generated in the underlying layer may be reduced, even though the process pressure is relatively high. Since the residual time of the first source gas in the process chamber 502 may be relatively longer during the formation of the first metal composite layer, halogen elements may react with the materials in the underlying layer. However, the first metal composite layer may sufficiently have desired step coverage by controlling the process temperature.

If the first metal composite layer is formed at a relatively low process pressure of about 2 Torr and a relatively high process temperature of about 700° C., the first metal composite layer may sufficiently have desired step coverage, even though the thermal stress generated in the underlying layer may not be reduced.

As described above, the fifth flow rate of the first source gas in the deposition of the third metal compound layer may be substantially greater than the first flow rate of the first source gas in the deposition of the first metal compound layer. On the contrary, the sixth flow rate of the second source gas during the formation of the third metal compound layer may be substantially lower or equal to the second flow rate of the second source gas during the formation of the first metal compound layer. Thus, the third metal compound layer may be deposited by the surface reaction between the first and the second source gases without the mass transfer between the first and the second source gases. That is, a flow rate ratio between the first and the second source gases may be relatively increased in the deposition of the third metal compound layer if the fifth flow rate is higher than the first flow rate and the sixth flow rate is lower than the second flow rate. Accordingly, the third metal compound layer may have good step coverage due to the surface reaction without the mass transfer.

In example embodiments of the present invention, an etching solution and/or an etching gas may not permeate into an underlying layer through a metal composite layer. Hence, etched damages to the underlying layer and/or the substrate may be effectively prevented.

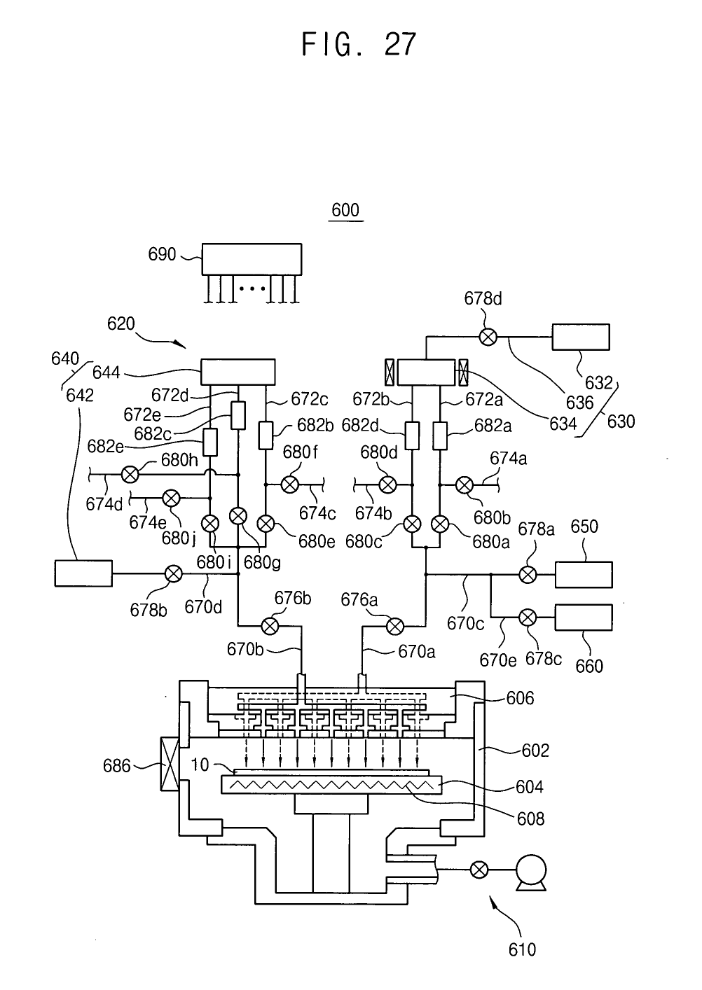

FIG. 27 is a cross-sectional view illustrating an apparatus for depositing a metal compound layer in accordance with another example embodiment of the present invention.

Referring to FIG. 27, an apparatus 600 to deposit a metal compound layer may be employed in a deposition process to form a metal composite layer for example, a titanium nitride layer on a semiconductor substrate 10. The apparatus 600 may include a process chamber 602, a stage 604, a vacuum system 610, and a gas supply system 620.

The gas supply system 620 may provide a first source gas and a second source gas onto the substrate 10 positioned in the process chamber 602 to form the metal composite layer on the substrate 10. The gas supply system 620 may be connected to a showerhead 606 disposed at an upper portion of the process chamber 602.

The first source gas may include a TiCl₄ gas and the second source gas may include an NH₃ gas if a titanium nitride layer is formed on the substrate 10. The first source gas and the second source gas may be carried into the process chamber 602 using a first carrier gas and a second carrier gas, respectively. The gas supply system 620 may further provide a purging gas and a cleaning gas into the process chamber 602 so as to purge and to clean an interior of the process chamber 602.

The gas supply system 620 may include a first gas supply unit 630 to provide the first source gas (e.g., the TiCl₄ gas) and the first carrier gas, a second gas supply unit 640 to provide the second source gas (e.g., the NH₃ gas) and the second carrier gas, a third gas supply unit 650 to provide the purging gas, and a fourth gas supply unit 660 to provide the cleaning gas. The gas supply system 620 may be connected to the showerhead 606 through a plurality of connection lines.

The first gas supply unit 630 may have a first reservoir 632 to store the first carrier gas, a sealed container 634 to store a first liquid source (e.g., liquid phase TiCl₄), and an immersed line 636 extending from the first reservoir 632 into the sealed container 634. The second gas supply unit 640 may include a second reservoir 642 to store the second carrier gas, and a second source gas tank 644 to provide the second source gas (e.g., the NH₃ gas).

The showerhead 606 may be connected to the sealed container 634 of the first gas supply unit 630 through a first connection line 670a, a first divided line 672a, and a second divided line 672b. The first and the second divided lines 672a and 672b may be branched from the first connection line 670a. The showerhead 606 may be connected to the second source gas tank 644 of the second gas supply unit 640 through a second connection line 670b, a third divided line 672c, a fourth divided line 672d, and a fifth divided line 672e. The third to the fifth divided lines 672c, 672d, and 672e may be branched from the second connection line 670b. The third gas supply unit 650 may be connected to the first connection line 670a through a third connection line 670c, and the second reservoir 642 of the second gas supply unit 640 may be connected to the second connection line 670b through a fourth connection line 670d. The fourth gas supply unit 660 may be connected to the third connection line 670c through a fifth connection line 670e so as to provide the cleaning gas into the process chamber 602 to clean the interior of the process chamber 602.

A first bypass line 674a, a second bypass line 674b, a third bypass line 674c, a fourth bypass line 674d, and a fifth bypass line 674e may be connected to the first divided line 672a, the second divided line 672b, the third divided line 672c, the fourth divided line 672d, and the fifth divided line 672e, respectively.

A first gate valve 676a and a second gate valve 676b may be respectively disposed in the first connection line 670a and the second connection line 670b. A first flow control valve 678a, a second flow control valve 678b, a third flow control valve 678c, and a fourth flow control valve 678d may be installed in the third connection line 670c, the fourth connection line 670d, the fifth connection line 670e, and the immersed line 636, respectively. A first interlocking valve 680a, a second interlocking valve 680b, a third interlocking valve 680c, a fourth interlocking valve 680d, a fifth interlocking valve 680e, a sixth interlocking valve 680f, a seventh interlocking valve 680g, an eighth interlocking valve 680h, a ninth interlocking valve 680i, and a tenth interlocking valve 680j may be disposed in the first divided line 672a, the first bypass line 674a, the second divided line 672b, the second bypass line 674b, the third divided line 672c, the third bypass line 674c, the fourth divided line 672d, the fourth bypass line 674d, the fifth divided line 672e, and the fifth bypass line 674e, respectively.

A first mass flow controller 682a may be disposed in the first divided line 672a to adjust a flow rate of the first source gas at a first flow rate. A second mass flow controller 682b may be installed in the third divided line 672c to thereby adjust a flow rate of the second source gas at a second flow rate. A third mass flow controller 682c may be disposed in the fourth divided line 672d to adjust a flow rate of the second source gas at a third flow rate. A fourth mass flow controller 682d may be installed in the second divided line 672b to adjust a flow rate of the first source gas at a fourth flow rate. A fifth mass flow controller 682e may be disposed in the fifth divided line 672e to adjust a flow rate of the second source gas at a fifth flow rate.

While the first source gas and the second source gas may be provided onto the substrate 10 at the first flow rate and the second flow rate in order to deposit a first metal compound layer on the substrate 10, the first and the fifth interlocking valves 680a and 680e may be opened, whereas the second and the sixth interlocking valves 680b and 680f may be closed. Simultaneously, the third interlocking valve 680c may be closed and the fourth interlocking valve 680d may be opened so as to bypass the first source gas with the fourth flow rate. Further, to bypass the second source gas with the third and the fifth flow rates, the seventh and the ninth interlocking valves 680g and 680i may be closed but the eighth and the tenth interlocking valves 680h and 680j may be opened.

After the formation of the first metal compound layer, the seventh interlocking valve 680g may be opened and the eight interlocking valve 680h may be closed while stopping a supply of the first source gas and providing the second source gas onto the first metal compound layer with the third flow rate in order to form a second metal compound layer on the first metal compound layer. At the same time, the first and the third interlocking valves 680a and 680c may be closed but the second and the fourth interlocking valves 680b and 680d may be opened so as to bypass the first source gas with the first and the fourth flow rates. Additionally, the fifth and the ninth interlocking valves 680e and 680i may be closed, whereas the sixth and the tenth interlocking valves 680f and 680h may be opened in order to bypass the second source gas with the second and the fifth flow rates. The second metal compound layer may be continuously deposited on the first metal compound layer by a reaction between the second source gas provided at the third flow rate and the residual first source gas in the process chamber 602. At the same time, chlorine contained in the first and the second metal compound layers may be removed by the second source gas provided at the third flow rate.

After depositing the second metal compound layer, the third and the ninth interlocking valves 680c and 680i may be opened but the fourth and the tenth interlocking valves 680d and 680j may be closed while the first and the second source gases may be provided onto the second metal compound layer with the fourth and the fifth flow rates so as to form a third metal compound layer on the second metal compound layer. Simultaneously, the first interlocking valve 680a may be closed and the second interlocking valve 680b may be opened in order to bypass the first source gas with the first flow rate. In addition, the fifth and the seventh interlocking valves 680e and 680g may be closed but the sixth and the eighth interlocking valves 680f and 680h may be opened so as to bypass the second source gas with the second and the third flow rates.

After the formation of the third metal compound layer, the seventh interlocking valve 680g may be opened and the eight interlocking valve 680h may be closed while stopping a supply of the first source gas and providing the second source gas onto the third metal compound layer with the third flow rate so as to form a fourth metal compound layer on the third metal compound layer. At the same time, the first and the third interlocking valves 680a and 680c may be closed but the second and the fourth interlocking valves 680b and 680d may be opened in order to bypass the first source gas with the first and the fourth flow rates. In addition, the fifth and the ninth interlocking valves 680e and 680i may be closed, whereas the sixth and the tenth interlocking valves 680f and 680h may be opened so as to bypass the second source gas with the second and the fifth flow rates. The fourth metal compound layer may be continuously deposited on the third metal compound layer by a reaction between the second source gas provided at the third flow rate and residual first source gas in the process chamber 602. At the same time, chlorine contained in the third and the fourth metal compound layers may be removed by the second source gas provided at the third flow rate.

A valve control unit 690 may adjust operations of the first to the tenth interlocking valves 680a, 680b, 680c, 680d, 680e, 680f, 680g, 680h, 680i, and 680j, operations of the first and the second gate valves 676a and 676b, and performances of the first to the fourth flow control valves 678a, 678b, 678c, and 678d.

The stage 604 may include a heater 608 to apply heat to the substrate 10 to a process temperature. A gate door 686 may be disposed at a sidewall of the process chamber 602 so that the substrate 10 may be loaded/unloaded into/from the process chamber 602 through the gate door 686. The vacuum system 610 coupled to the process chamber 602 may remove reaction byproducts generated in the formation of the metal composite layer and residual first source gases in the process chamber 602.

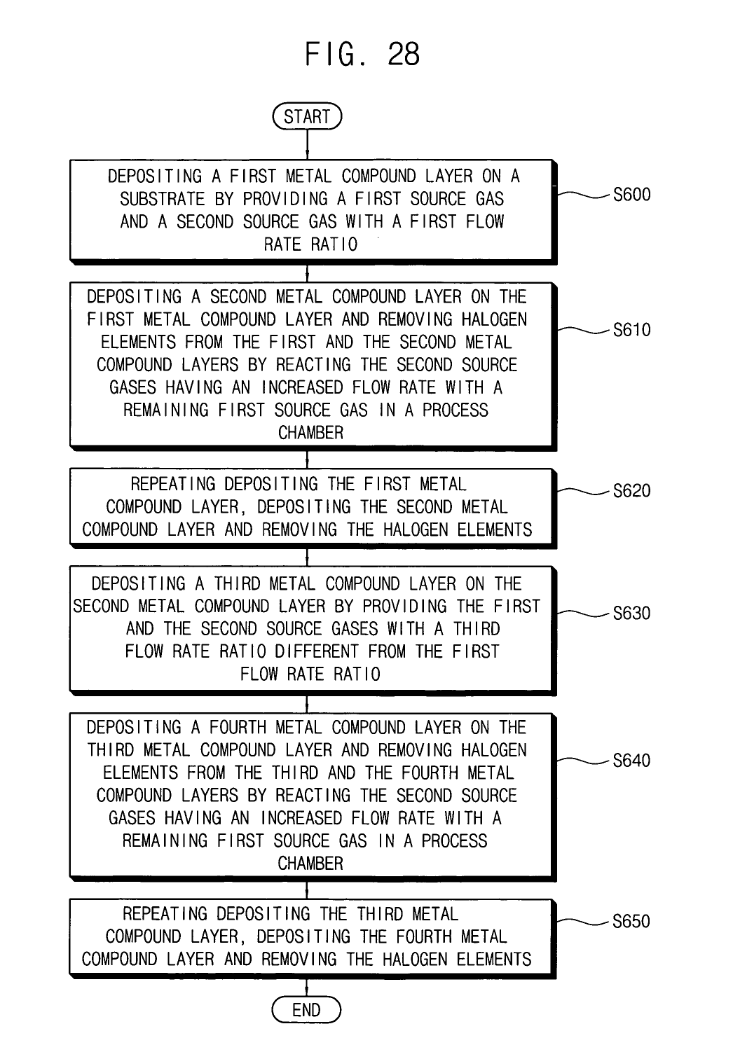

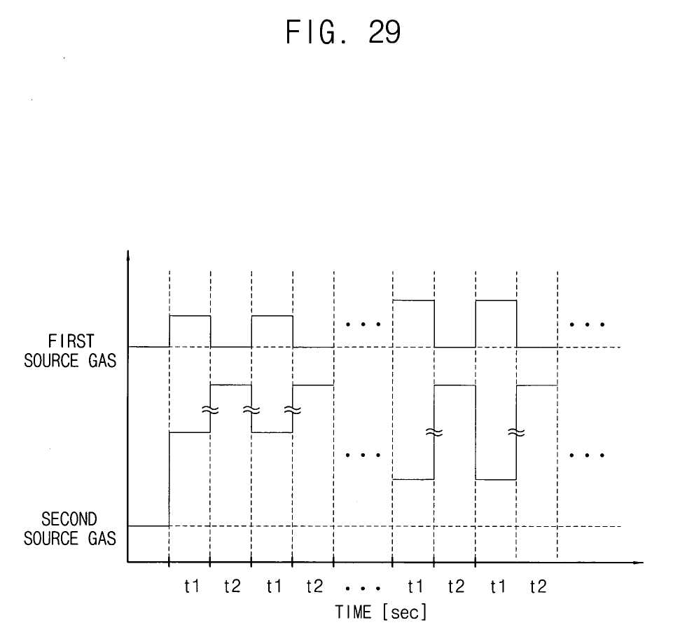

FIG. 28 is a flow chart illustrating a method of depositing a metal compound layer on a substrate using the apparatus of FIG. 27 in accordance with an example embodiment of the present invention. FIG. 29 is a timing diagram illustrating feeding times of source gases used in the method illustrated in FIG. 28.

Referring to FIGS. 27 to 29, in S600, a first metal compound layer may be deposited on a substrate 10 by providing a first source gas and a second source gas onto the substrate 10 at a first flow rate ratio. The first source gas may include a metal and halogen elements, and the second source gas may include a first material capable of reacting with the metal in the first source gas and a second material capable of being reacted with the halogen element in the first source gas. For example, the first source gas may include a TiCl₄ gas, and the second source gas may include an NH₃ gas.

During the deposition of the first metal compound layer, first and the second mass flow controllers 682a and 682b may independently adjust the first flow rate of the first source gas and the second flow rate of the second source gas. The first flow rate ratio between the first flow rate of the first source gas and the second flow rate of the second source gas may be determined within a range in which the first metal compound layer may be deposited by a surface reaction between the first and the second source gases rather than a mass transfer between the first and the second source gases.

In an example embodiment of the present invention, the first flow rate ratio between the first and the second flow rates of the first and the second source gases may be in a range of about 1.0:2.0 to about 1.0:10. In other words, the first flow rate may be in a range of about 0.1:1.0 to about 0.5:1.0. Thus, undesired materials for example, chlorine may be effectively removed from the first metal compound layer because the second flow rate of the second source gas may be relatively lower than the first flow rate of the first source gas. For example, the first flow rate of the first source gas may be about 20 sccm by the first mass flow controller 682a, and the second flow rate of the second source gas may be about 60 sccm by the second mass flow controller 682b.

In S610, the supply of the first source gas may be ceased and the second source gas may be provided onto the first metal compound layer with a third flow rate substantially greater than the second flow rate. Accordingly, the second metal compound layer may be deposited on the first metal compound layer by the reaction between the second source gas provided at the third flow rate and a residual first source gas in the process chamber 602. Simultaneously, undesired materials may be removed from the first and the second metal compound layers by the reaction between the second source gas provided at the third flow rate and the residual first source gas.

In an example embodiment of the present invention, a third mass flow controller 682c may adjust the third flow rate of the second source gas. A flow rate ratio between the second flow rate and the third flow rate may be in a range of about 1.0:100 to about 1.0:1,000. For example, the third flow rate of the second source gas may be about 1,000 sccm.

In an example embodiment of the present invention, the first and the third interlocking valves 680a and 680c may cease the supply of the first source gas in the S610. Since the residual first source gas provided in S600 may react with the second source gas provided in S610m, the second metal compound layer may be continuously deposited on the first metal compound layer. If a process time in S610 is sufficiently long, the flow rate of the first source gas during the formation of the second metal compound layer may be gradually reduced from the first flow rate, and then the residual first source gas may be completely consumed after the formation of the second metal compound layer. When the process time in S610 is relatively short, the residual first source gas may be continuously reacted with the second source gas to thereby contribute to the formation of the second metal compound layer.

In S620, a first metal composite layer having a desired thickness may be formed on the substrate 10 by repeating in series process S600 and S610. The first composite layer may include the first and the second metal compound layers.

In S630, a third metal compound layer may be deposited on the first metal composite layer by providing the first and the second source gases with a fourth flow rate and a fifth flow rate, respectively. The fourth flow rate may be substantially greater than the first flow rate, whereas the fifth flow rate may be substantially lower than or equal to the second flow rate. The fourth mass flow controller 682d may adjust the fourth flow rate of the first source gas, and the fifth mass flow controller 682e may adjust the fifth flow rate of the second source gas. A flow rate ratio between the fourth and the fifth flow rates may be in a range of about 1.0:0.5 to about 1.0:2.0. For example, the fourth flow rate of the first source gas may be about 30 sccm, and the fifth flow rate of the second source gas may be about 30 sccm.

In S640, a fourth metal compound layer may be continuously deposited on the third metal compound layer, and chlorine contained in the third and the fourth metal compound layers may be simultaneously removed by stopping the supply of the first source gas and providing the second source gas with the sixth flow rate substantially equal to the third flow rate. The third mass flow controller 682c may advantageously adjust the sixth flow rate of the second source gas. The fourth metal compound layer may be deposited through a process substantially to the same as those of the second metal compound layer.

In S650, a second metal composite layer having a desired thickness may be formed on the first composite layer by repeating in series process S630 and S640. The second composite layer may include the third and the fourth metal compound layers.

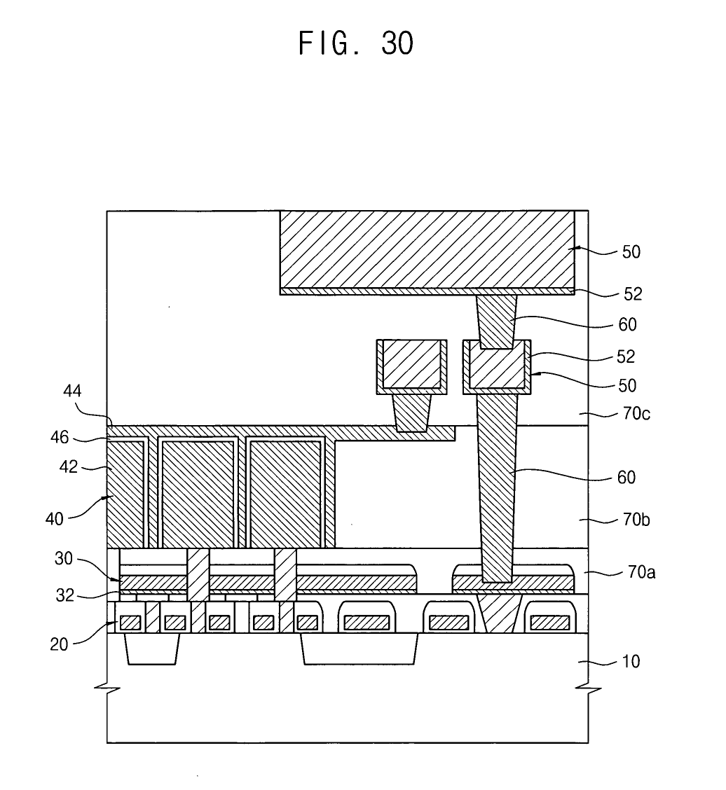

FIG. 30 is a cross-sectional view illustrating a semiconductor device including a titanium nitride layer in accordance with an example embodiment of the present invention.

Referring to FIG. 30, a plurality of field effect transistors 20 may be formed on a semiconductor substrate 10. Bit line structures 30 may be formed on the transistors 20, and capacitors 40 to store data may be formed on the bit line structures 30.

A first set of transistors 20 positioned in a cell area of the substrate 10 may be electrically connected to the bit line structures 30 and the capacitors 40. Each of the capacitors 40 may include a lower electrode 42, a dielectric layer 44 and an upper electrode 46. A second set of transistors 20 may be electrically connected to metal wiring structures 50 through contact plugs 60. The metal wiring structures 50 may be positioned on the capacitors 40.

The above-described structures may be separated by interposing insulating inter layers 70a, 70b, and 70c. Those structures may be formed through general semiconductor manufacturing technology unit processes.

The lower electrode 42 and/or the upper electrode 44 of the capacitor 40 may be formed by the above-described deposition processes and apparatuses to deposit a metal compound layer in accordance with example embodiments of the present invention. If the dielectric layer 46 includes a high-k material, the reaction between halogen elements and the high-k material may be effectively suppressed because the lower electrode 42 and/or the upper electrode 44 may be formed using a TiCl₄ gas having a relatively small flow rate at a relatively low process temperature. Therefore, a leakage current from the lower electrode 42 and/or the upper electrode 44 may be greatly reduced, whereas a specific resistance of the lower electrode 42 and/or the upper electrode 44 may be improved.

Metal barrier layers 32 and 52 may be formed between the insulating inter layers 70a, 70b, and 70c and the conductive structures for example, the bit lines 30 and the metal wiring structures 50. The metal barrier layers 32 and 52 may also be formed by the above-described deposition processes and apparatuses to deposit a metal compound layer in accordance with example embodiments of the present invention. Since the metal barrier layers 32 and 52 may be formed at a relatively low process temperature, thermal stresses applied to underlying structures may be reduced and electrical resistances between the underlying structures and the conductive structures for example, the bit lines 30 and the metal wiring structures 50 may be decreased.

The contact plugs 60 may be electrically connect the transistors 20 to the metal wiring structures 50. The contact plugs 60 may also be formed by the above-described deposition processes and apparatuses to deposit a metal compound layer in accordance with example embodiments of the present invention. Because the contact plugs 60 may be formed at a relatively low process temperature, thermal stresses applied to underlying structures may be reduced and electrical resistances between the underlying structures and the conductive structures for example, the bit lines 30 and the metal wiring structures 50 may be decreased.

According to the present invention, a first metal compound layer may be deposited on a substrate using a first source gas and a second source gas. A second metal compound layer may be continuously deposited on the first metal compound layer by controlling flow rates of the first and the second source gases. Undesired materials may be simultaneously removed from the first and the second metal compound layers in the formation of a metal composite layer. Thus, the metal composite layer may have greatly reduced resistance, and a manufacturing throughput of the metal composite layer may be considerably improved in comparison with that of a conventional ALD process or the conventional SFD process.

Additionally, the metal composite layer may be formed at a relatively low process temperature and process pressure so that a thermal stress that may be generated in an underlying structure may decrease and the metal compound layer may have good step coverage. If the underlying structure includes a high-k material, a reaction between a halogen element in the metal composite layer and the high-k material may be effectively suppressed, thereby greatly reducing a leakage current from the metal composite layer through the underlying structure.

Furthermore, the metal composite layer may have a composite structure that includes a plurality of metal compound layers so that etched damage to the underlying structure may be sufficiently suppressed by preventing an etching solution and/or an etching gas from permeating the metal composite layer in successive etching processes.

The foregoing is illustrative of example embodiments of the present invention and is not to be construed as limiting thereof. Although several example embodiments of the present invention have been described, those skilled in the art will readily appreciate that many modifications are possible in the example embodiments without materially departing from the novel teachings and aspects of the present invention. Accordingly, all such modifications are intended to be included within the scope of the present invention. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the present invention.

What is claimed is:

1. A method of depositing a metal compound layer, comprising:
providing a first source gas including a metal and a second source gas including a material capable of reacting with the metal onto a substrate to deposit a first metal compound layer on the substrate, wherein the first and the second source gases are provided at a first flow rate ratio in which a deposition rate of the first metal compound layer by a surface reaction between the first and the second source gases is substantially higher than a deposition rate of the first metal compound layer by a mass transfer between the first and the second source gases; and
providing the first and the second source gases at a second flow rate ratio different then the first flow rate ratio to deposit a second metal compound layer on the first metal compound layer, wherein the first and the second source gases simultaneously remove undesired materials from the first and the second metal compound layers.

2. The method of claim 1, wherein the first source gas includes TiCl₄, and the second source gas includes NH₃.

3. The method of claim 1, wherein the first flow rate ratio is in a range of about 1.0:0.5 to about 1.0:10, and the second flow rate ratio is in a range of about 1.0:100 to about 1.0:1,000.

4. The method of claim 1, wherein a flow rate of the first source gas during the formation of the first metal compound layer is greater than a flow rate of the first source gas during the formation of the second metal compound layer.

5. The method of claim 1, wherein a flow rate of the second source gas during the formation of the second metal compound layer is greater than a flow rate of the second source gas during the formation of the first metal compound layer.

6. The method of claim 5, wherein a third flow rate ratio between the flow rate of the second source gas during the formation of the first metal compound layer and the flow rate of the second gas during the formation of the second metal compound layer is in a range of about 1.0:10 to about 1.0:100.

7. The method of claim 1, wherein the first and the second metal compound layers are deposited at a temperature of about 400 to about 600° C.

8. The method of claim 1, wherein the first and the second metal compound layers are deposited at a pressure of about 0.1 to about 2.5 Torr and a temperature of about 400 to about 700° C.

9. The method of claim 1, further including increasing a flow rate of the second source gas and reducing or ceasing a supply of the first source gas, wherein a residual first source gas reacts with the second source gas to deposit the second metal compound layer.

10. The method of claim 1, further including:
removing the undesired materials from the first metal compound layer by reducing or ceasing a supply of the first source gas and by providing the second source gas with a flow rate greater than a flow rate of the second source gas during the formation of the first metal compound layer; and
removing the undesired materials from the second metal compound layer by reducing or ceasing a supply of the first source gas and by providing the second source gas with a flow rate greater than a flow rate of the second source gas during the formation of the second metal compound layer.

11. A method of depositing a metal compound layer, comprising:
providing a first source gas including a metal and a second source gas including a material capable of reacting with the metal onto the substrate to deposit a first metal compound layer on the substrate, wherein the first and the second source gases are provided at a first flow rate ratio in which a deposition rate of the first metal compound layer by a surface reaction between the first and the second source gases is substantially higher than a deposition rate of the first metal compound layer by a mass transfer between the first and the second source gases;
providing the first and the second source gases with a second flow rate ratio different then the first flow rate ratio to deposit a second metal compound layer on the first metal compound layer;
providing the first and the second source gases with a third flow rate ratio different then the first flow rate ratio to deposit a third metal compound layer on the second metal compound layer to cause a surface reaction between the first and the second source gases; and
providing the first and the second source gases with a fourth flow rate ratio different then the third flow rate ratio to deposit a fourth metal compound layer on the third metal compound layer.

12. The method of claim 11, wherein the first source gas includes TiCl₄, and the second source gas includes NH₃.

13. The method of claim 11, wherein a flow rate of the first source gas is lower than a flow rate of the second source gas during the formation of the first metal compound layer.

14. The method of claim 13, wherein the first flow rate ratio is in a range of about 1.0:2.0 to about 1.0:10.0.

15. The method of claim 11, wherein a flow rate of the first source gas during the formation of the first metal compound layer is greater than a flow rate of the first source gas during the formation of the second metal compound layer.

16. The method of claim 11, wherein a deposition rate of the second metal compound layer by a surface reaction between the first and the second source gases is similar to a deposition rate of the second metal compound layer by a mass transfer between the first and the second source gases.

17. The method of claim 16, wherein the second flow rate ratio is in a range of about 1.0:100 to about 1.0:1,000.

18. The method of claim 11, wherein a flow rate of the second source gas during the formation of the second metal compound layer is greater than a flow rate of the second source gas during the formation of the first metal compound layer.

19. The method of claim 18, wherein a flow rate ratio between the flow rate of the second source gas during the formation of the first metal compound layer and the flow rate of the second source gas during the formation of the second metal compound layer is in a range of about 1.0:10 to about 1.0:100.

20. The method of claim 11, wherein a flow rate of the first source gas during formation of the third metal compound layer is greater than a flow rate of the first source gas during the formation of the first metal compound layer.

21. The method of claim 11, wherein the third flow rate ratio is in a range of about 1.0:0.5 to about 1.0:2.0.

22. The method of claim 11, wherein the second flow rate ratio is similar to the fourth flow rate ratio.

23. The method of claim 22, wherein a flow rate of the first source gas during the formation of the second metal compound layer is similar to a flow rate of the first source gas during a formation of the fourth metal compound layer.

24. The method of claim 11, wherein the first to the fourth metal compound layers are deposited at a temperature of about 400 to about 600° C.

25. The method of claim 11, wherein the first to the fourth metal compound layers are deposited at a pressure of about 0.1 to about 2.5 Torr and a temperature of about 400 to about 700° C.

26. The method of claim 11, wherein depositing the first metal compound layer and depositing the second metal compound layer are repeated in series to form a first metal composite layer on the substrate.

27. The method of claim 26, wherein the first metal composite layer is formed to a thickness of about 30 to about 100 Å.

28. The method of claim 26, wherein depositing the third metal compound layer and depositing the fourth metal compound layer are repeated in series to form a second metal composite layer on the first metal composite layer.

29. The method of claim 28, wherein the first and the second metal composite layers form a lower electrode or an upper electrode for a capacitor.

30. The method of claim 28, wherein the first and the second metal composite layers form a metal barrier layer.

31. The method of claim 28, wherein the first and the second metal composite layers form a plug that connects lower structures to upper structures.

32. A method of depositing a metal compound layer, comprising:
providing a first source gas including a metal and a second source gas including a material capable of reacting with the metal onto a substrate to deposit a first metal compound layer on the substrate, wherein the first and the second source gases are provided at a first flow rate ratio in which a deposition rate of the first metal compound layer by a surface reaction between the first and the second source gases is substantially higher than a deposition rate of the first metal compound layer by a mass transfer between the first and the second source gases;
providing the second source gas at an increased flow rate and reducing or ceasing a supply of the first source gas onto the first metal compound layer, wherein the second source gas reacts with a residual first source gas to deposit a second metal compound layer on the first metal compound layer;
providing the first and the second source gases at a second flow rate ratio different than the first flow rate ratio to cause a surface reaction between the first and the second source gases to deposit a third metal compound layer on the second metal compound layer; and
providing the second source gas at an increased flow rate and reducing or ceasing a supply of the first source gas onto the third metal compound layer, wherein the second source gas reacts with a residual first source gas to deposit a fourth metal compound layer on the third metal compound layer.

33. The method of claim 32, wherein the first source gas includes halogen, and the second source gas includes a material capable of reacting with the halogen to deposit the first metal compound layer.

34. The method of claim 33, further including:
providing the first and the second source gases to deposit the first metal compound layer at a first flow rate and a second flow rate, respectively;
removing the halogen from the first and the second metal compound layers by providing the first source gas with a third flow rate lower than the first flow rate and by providing the second source gas with a fourth flow rate greater than the second flow rate, and the formation of the second metal compound layer and removing the halogen are simultaneous;
providing the first source gas with a fifth flow rate greater than the first flow rate and by providing the second source gas with a sixth flow rate similar to or lower than the second flow rate to deposit the third metal compound layer on the second metal compound layer; and
removing the halogen from the third and the fourth metal compound layers by providing the first source gas with a seventh flow rate similar to the third flow rate and by providing the second source gas with an eighth flow rate similar to the fourth flow rate, and the formation of the fourth metal compound layer and removing the halogen are simultaneous.

35. The method of claim 34, wherein a flow rate ratio between the first and the second flow rates is in a range of about 1.0:2.0 to about 1.0:10, a flow rate ratio between the third and the fourth flow rates is in a range of about 1.0:100 to about 1.0:1,000, and a flow rate ratio between the fifth and the sixth flow rates is in a range of about 1.0:0.5 to about 1.0:2.0.

36. The method of claim 34, further including:
reducing or ceasing a supply of the first source gas and by providing the second source gas at a third flow rate greater than the second flow rate to react the second source gas with the residual first source gas to deposit the second metal compound layer on the first metal compound layer and simultaneously remove the halogen;
providing the first source gas with a fourth flow rate greater than the first flow rate and providing the second source gas with a fifth flow rate similar to or lower than the second flow rate to deposit the third metal compound layer on the second metal compound layer; and
reducing or ceasing a supply of the first source gas and by providing the second source gas with a sixth flow rate similar to the third flow rate to react the second source gas with the residual first source gas to deposit the fourth metal compound layer on the third metal compound layer and simultaneously remove the halogen.

37. An apparatus to deposit a metal compound layer, comprising:
a process chamber configured to receive a substrate;
a gas supply system configured to provide a first source gas and a second source gas onto the substrate, wherein the first source gas includes a metal and the second source gas includes a material capable of reacting with the metal; and
a flow rate control device configured to adjust flow rates of the first and the second source gases to deposit a first metal compound layer on the substrate, wherein the first and the second source gases are provided at a first flow rate ratio, and also configured to adjust the flow rates of the first and the second source gases to deposit a second metal compound layer on the first metal compound layer and simultaneously to remove undesired materials from the first and the second metal compound layers, wherein the first and the second source gases are provided at a second flow rate ratio different from the first flow rate ratio.

38. The apparatus of claim 37, wherein the flow rate control device includes:
a first flow rate control member including a first mass flow controller and a second mass flow controller configured to adjust the flow rates of the first and the second source gases to the first flow rate ratio; and
a second flow rate control member including a third mass flow controller and a fourth mass flow controller configured to adjust the flow rates of the first and the second source gases to the second flow rate ratio.

39. The apparatus of claim 37, wherein the flow rate control device includes:
a first flow rate control member including a first mass flow controller configured to adjust the flow rate of the first source gas with respect to the second source gas to the first flow rate ratio; and
a second flow rate control member including a second mass flow controller and a third mass flow controller configured to adjust the flow rate of the second source gas with respect to the first source gas to the second flow rate ratio.

40. The apparatus of claim 37, wherein the flow rate control device includes
a first flow rate control member including a first mass flow controller and a third mass flow controller configured to adjust the flow rate of the first source gas with respect to the second source gases to the first flow rate ratio; and
a second flow rate control member including a second mass flow controller configured to adjust the flow rate of the second source gas with respect to the first source gas to the second flow rate ratio.

41. The apparatus of claim 37, wherein the flow rate control device includes
a first flow rate control member including a first mass flow controller configured to adjust the flow rate of the first source gas with respect to the second source gases to the first flow rate ratio; and
a second flow rate control member including a second mass flow controller configured to adjust the flow rate of the second source gas with respect to the first source gas to the second flow rate ratio.

42. The apparatus of claim 37, wherein the flow rate control device includes:
a first flow rate control member including a first mass flow controller to adjust a first flow rate of the first source gas, a third mass flow controller to adjust a third flow rate of the first source gas, and a fifth mass flow controller to adjust a fifth flow rate of the first source gas;
a second flow rate control member including a second mass flow controller to adjust a second flow rate of the second source gas, a fourth mass flow controller to adjust a fourth flow rate of the second source gas, and a sixth mass flow controller to adjust a sixth flow rate of the first source gas.

43. The apparatus of claim 37, wherein the flow rate control device includes:
a first flow rate control member including a first mass flow controller to adjust a first flow rate of the first source gas, and a fourth mass flow controller to adjust a fourth flow rate of the first source gas;
a second flow rate control member including a second mass flow controller to adjust a second flow rate of the second source gas, a third mass flow controller to adjust a third flow rate of the second source gas, and a fifth mass flow controller to adjust a fifth flow rate of the first source gas.

44. The apparatus of claim 37, further comprising a showerhead disposed at an upper portion of the process chamber to uniformly provide the first and the second source gases onto the substrate.

45. The apparatus of claim 44, wherein the gas supply system includes:
a first gas supply unit configured to provide the first source gas; and,
a second gas supply unit for providing the second source gas, and wherein the gas supply system is connected to the showerhead through a plurality of connection lines, and the connection lines includes a first connection line connected to the showerhead to provide the first source gas, and a second connection line connected to the showerhead to provide the second source gas.

46. The apparatus of claim 45, wherein the gas supply system further includes:
a third gas supply unit configured to provide a purging gas into the process chamber; and
a fourth gas supply unit configured to provide a cleaning gas into the process chamber.
